(19) United States
(12) Patent Application Publication
(10) Pub. No.: US 2025/0240973 A1
(43) Pub. Date: Jul. 24, 2025

(54) FERROELECTRIC NON-VOLATILE MEMORY AND METHODS OF FORMATION

(71) Applicant: Taiwan Semiconductor Manufacturing Company, Ltd., Hsinchu (TW)

(72) Inventors: Yen-Chieh HUANG, Changhua County (TW); Huai-Ying HUANG, New Taipei City (TW); Wei-Gang CHIU, New Taipei City (TW); I-Chee LEE, Taipei City (TW); Yu-Ming LIN, Hsinchu City (TW)

(21) Appl. No.: 18/416,715

(22) Filed: Jan. 18, 2024

(51) Int. Cl. H10B 51/30; H01L 29/45; H01L 29/78; H01L 29/786

(52) U.S. Cl. CPC H10B 51/30; H10D 30/6755; H10D 30/701; H10D 64/62

(57) ABSTRACT

A multiple-layer hydrogen barrier stack may be included between a non-volatile memory structure and conductive structures in an interconnect structure in a semiconductor device. The multiple-layer hydrogen barrier stack may minimize and/or prevent hydrogen diffusion into one or more layers of the non-volatile memory structure such as a metal-oxide channel of the non-volatile memory structure. The multiple-layer hydrogen barrier stack may include a hydrogen absorption layer and a hydrogen blocking layer on the hydrogen absorption layer. The hydrogen blocking layer blocks or resists diffusion of hydrogen through the conductive structures into the non-volatile memory structure. The hydrogen absorption layer may absorb any hydrogen atoms that might diffuse through the hydrogen blocking layer.

### BACKGROUND

A ferroelectric random access memory (FeRAM) cell is a type of random-access memory cell that utilizes a ferroelectric field effect transistor (FeFET) that includes a ferroelectric (FE) layer to selectively store information based on polarization of the ferroelectric layer. For example, a first voltage may be applied to a gate structure of the FeFET to cause the ferroelectric layer to be polarized in a first polarization configuration corresponding to a programmed state of the FeRAM cell, and a second voltage may be applied to the gate structure to cause the ferroelectric layer to be polarized in a second polarization configuration corresponding to an erased state of the FeRAM cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIG. 3 is a diagram of an example implementation of a non-volatile memory structure described herein.

FIG. 4 is a diagram of an example implementation of a non-volatile memory structure described herein.

FIG. 5 is a diagram of an example implementation of a hydrogen barrier layer described herein.

FIGS. 6A-6F are diagrams of example implementations of hydrogen blocking layers described herein.

FIGS. 7A-7C are diagrams of example hydrogen concentrations in the semiconductor device for the example implementations of a hydrogen blocking layer illustrated and described in connection with FIGS. 6A-6F.

FIGS. 8A-8K are diagrams of an example implementation of forming the semiconductor device described herein.

FIGS. 9A and 9B are diagrams of example implementations of forming a hydrogen absorption layer of a hydrogen barrier layer described herein.

FIGS. 10A-10N are diagrams of an example implementation of forming the non-volatile memory structure described herein.

FIG. 11 is a diagram of example components of a device described herein.

FIG. 12 is a flowchart of an example process associated with forming a non-volatile memory structure described herein.

FIG. 13 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a ferroelectric random access memory (FeRAM) structure may include a metal-oxide channel layer (e.g., a channel layer that includes a metal-oxide material or a metal-oxide semiconductor material such as indium gallium zinc oxide (IGZO)) above a ferroelectric layer, and a plurality of source/drain electrodes adjacent to the metal-oxide channel layer. The use of a metal-oxide channel layer may enable reduced current leakage to be achieved in the FeRAM structure relative to an elemental semiconductor channel, a III-V semiconductor channel, or a II-VI semiconductor channel, among other examples.

However, metal-oxide materials are highly susceptible to hydrogen contamination. If hydrogen diffuses into the metal-oxide channel of the FeRAM structure, charge carrier concentration can be increased in the metal-oxide channel. The charge carrier concentration may increase due to low zinc-oxygen (Z—O) bond dissociation energy of the metal-oxide material of the metal-oxide channel. In particular, the bonds between zinc (Zn) and oxygen (O) in the metal-oxide material may easily break due to the low Z—O bond dissociation energy, resulting in zinc with oxygen vacancies (Zn-V_{O}) and free oxygen that bonds with diffused hydrogen to form water (H₂O) in the metal-oxide channel. The water and zinc oxide may promote retention of an electrical charge in the metal-oxide channel, resulting in the increased charge carrier concentration. The increased charge carrier concentration can cause increased off-current leakage for the FeRAM structure, increased positive bias temperature instability (PBTI), and/or increased negative bias temperature instability (NBTI), among other examples. Additionally and/or alternatively, hydrogen contamination in the metal-oxide semiconductor channel can increase the charge carrier concentration to a point where the FeRAM structure becomes stuck in a normally-on configuration, thereby rendering the FeRAM structure non-operational.

In some implementations described herein, an FeRAM structure is included in an interconnect structure of a semiconductor device. A multiple-layer hydrogen barrier stack is included between the FeRAM structure and the conductive structures in the interconnect structure to which source/drain electrodes of the FeRAM structure are connected. The multiple-layer hydrogen barrier stack may minimize and/or prevent hydrogen diffusion into one or more layers of the FeRAM structure such as a metal-oxide channel of the FeRAM structure. The multiple-layer hydrogen barrier stack may include a hydrogen absorption layer and a hydrogen blocking layer on the hydrogen absorption layer. The hydrogen blocking layer blocks or resists diffusion of hydrogen through the conductive structures into the FeRAM structure. The hydrogen absorption layer may absorb any hydrogen atoms that might diffuse through the hydrogen blocking layer.

In this way, the combination of the hydrogen absorption layer and the hydrogen blocking layer minimizes and/or prevents hydrogen diffusion into one or more layers of the FeRAM structure such as the metal-oxide channel of the FeRAM structure. This may reduce the likelihood of charge carrier concentration in the metal-oxide channel of the FeRAM structure, which may enable a low PBTI and/or a low NBTI to be achieved for the FeRAM structure. Additionally and/or alternatively, the combination of the hydrogen absorption layer and the hydrogen blocking layer may enable a low off-current leakage to be achieved for the FeRAM structure and/or may reduce the likelihood that the FeRAM structure may become non-operational because of charge carrier concentration.

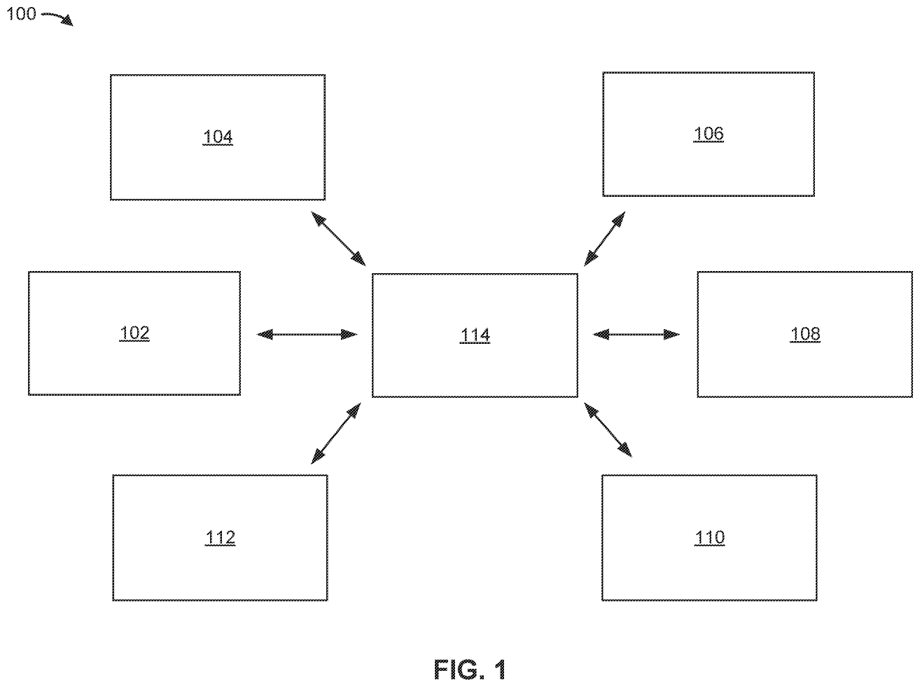

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

A sputtering (or sputter deposition) technique is a PVD technique that includes one or more techniques to deposit material onto a substrate or a wafer, such as a metal, a dielectric, or another type of material. For example, a sputtering process may include placing the substrate on an anode in a processing chamber, in which a gas (e.g., argon or another chemically inert gas) is supplied and ignited to form a plasma of ions of the gas. The ions in the plasma are accelerated from a cathode toward a sputtering target, which causes the ions to bombard the sputtering target and release particles of deposition material. The anode attracts the particles, which causes the particles to travel toward and deposit onto the wafer.

An ALD technique is a deposition technique that is used in the semiconductor manufacturing industry to form thin, conformal films with atomic level thickness control. An ALD operation includes the use of sequential gas-phase precursors (or reactants) that each separately react with a surface of a material in a self-limiting manner. A first gas-phase precursor is introduced into a processing chamber to react with the surface of the material. The first gas-phase precursor is then removed from the processing chamber, and a second gas-phase precursor is introduced into the processing chamber to react with the surface of the material, and so on. This alternating process is repeated to grow or otherwise form a film on the surface in a highly-controlled manner. Additional gas-phase precursors may be included in an ALD operation to deposit different atomic layers of material.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may be used to perform one or more semiconductor processing operations described herein. For example, one or more of the semiconductor processing tools 102-112 and/or the wafer/die transport tool 114 may be used to form a bottom gate electrode of a non-volatile memory structure; form a ferroelectric layer of the non-volatile memory structure above the bottom gate electrode; form a metal-oxide channel layer of the non-volatile memory structure above the ferroelectric layer; form a dielectric layer above the metal-oxide channel layer; form a source/drain electrode of the non-volatile memory structure at least one of adjacent to or above the metal-oxide channel layer; form a hydrogen absorption layer on the source/drain electrode; form a hydrogen blocking layer on the hydrogen absorption layer; and/or form a conductive structure on the hydrogen blocking layer, among other examples.

As another example, one or more of the semiconductor processing tools 102-112 and/or the wafer/die transport tool 114 may be used to form a first portion of an interconnect structure, of a semiconductor device, above a substrate; form a non-volatile memory structure the first portion of the interconnect structure; and/or form a second portion of the interconnect structure above the first portion of the interconnect structure and above the non-volatile memory structure, where forming the second portion of the interconnect structure includes: forming one or more dielectric layers above the first portion of the interconnect structure; forming a recess in the one or more dielectric layers, where a first conductive structure in the first portion of the interconnect structure is exposed through the recess; forming a hydrogen barrier layer on the first conductive structure in the recess; and/or forming a second conductive structure on the hydrogen barrier layer in the recess, among other examples.

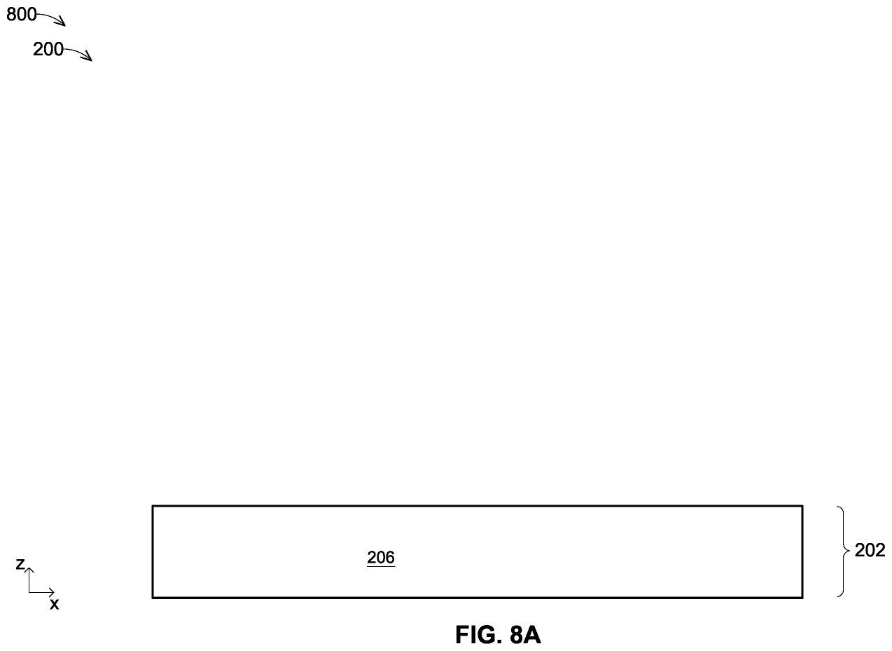

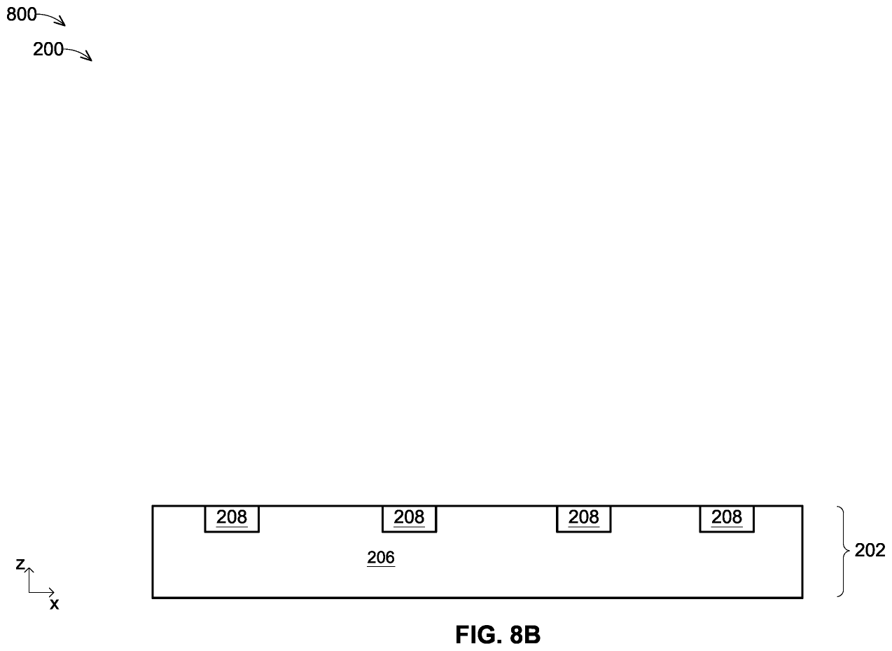

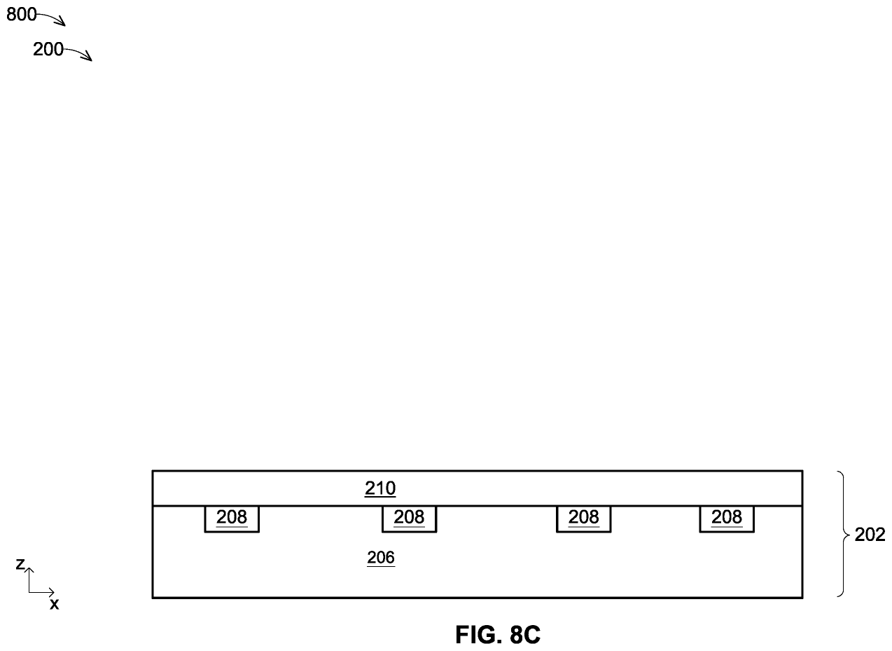

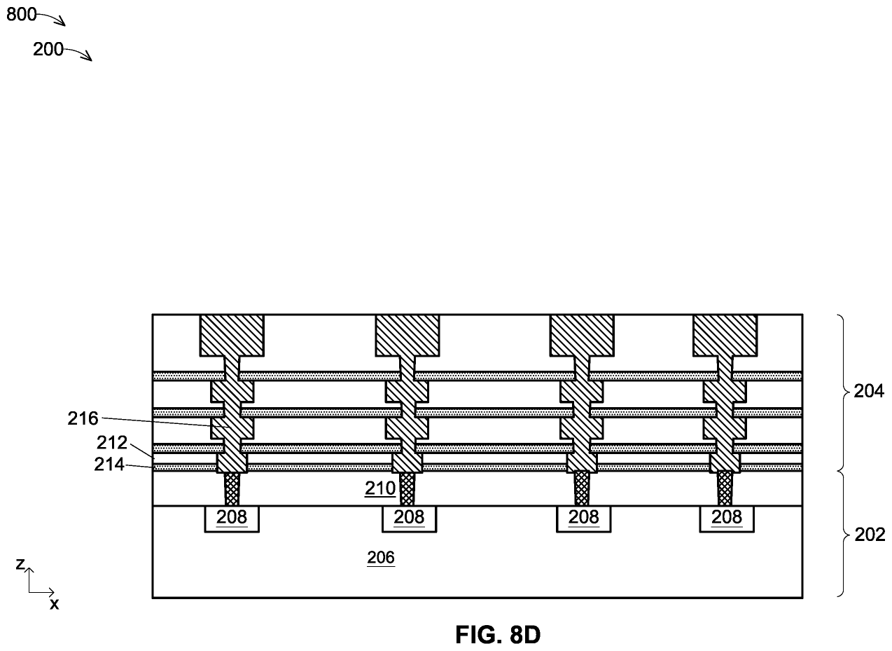

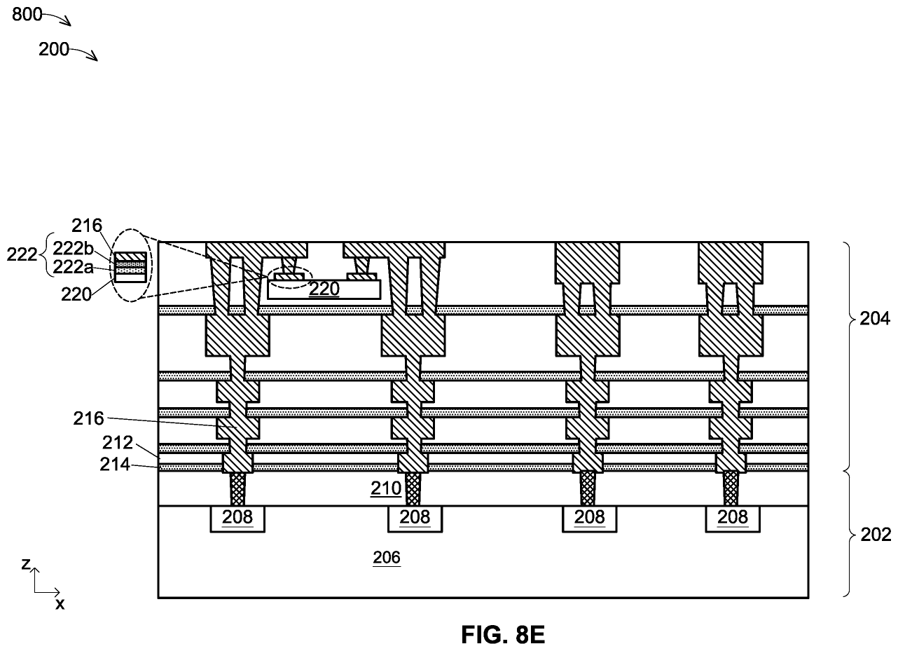

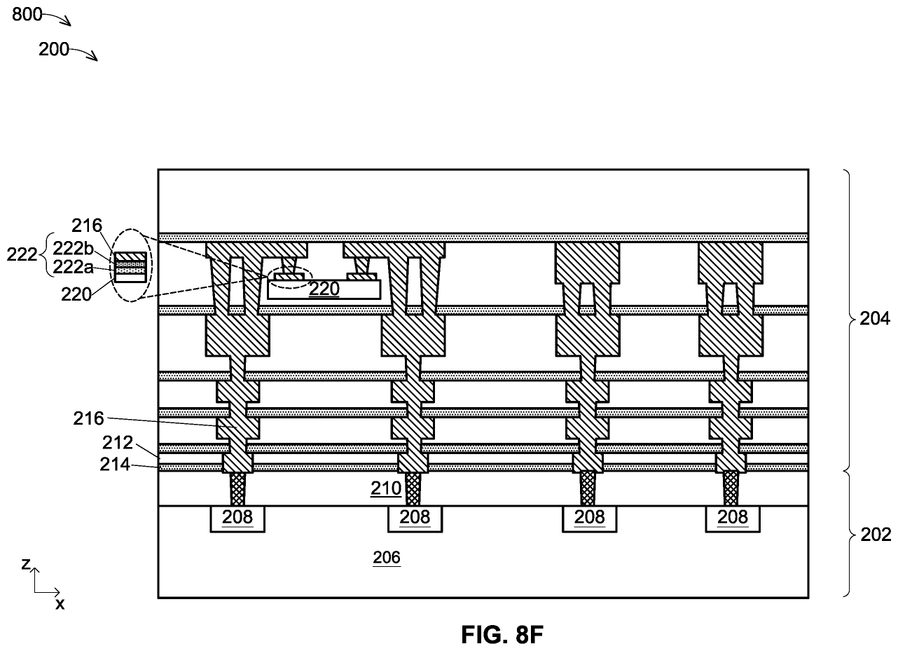

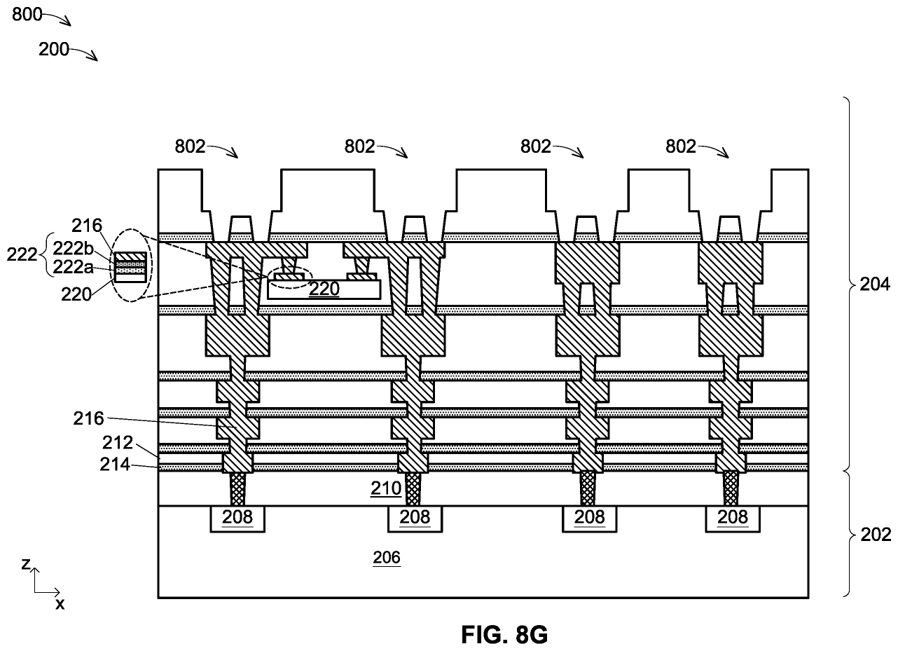

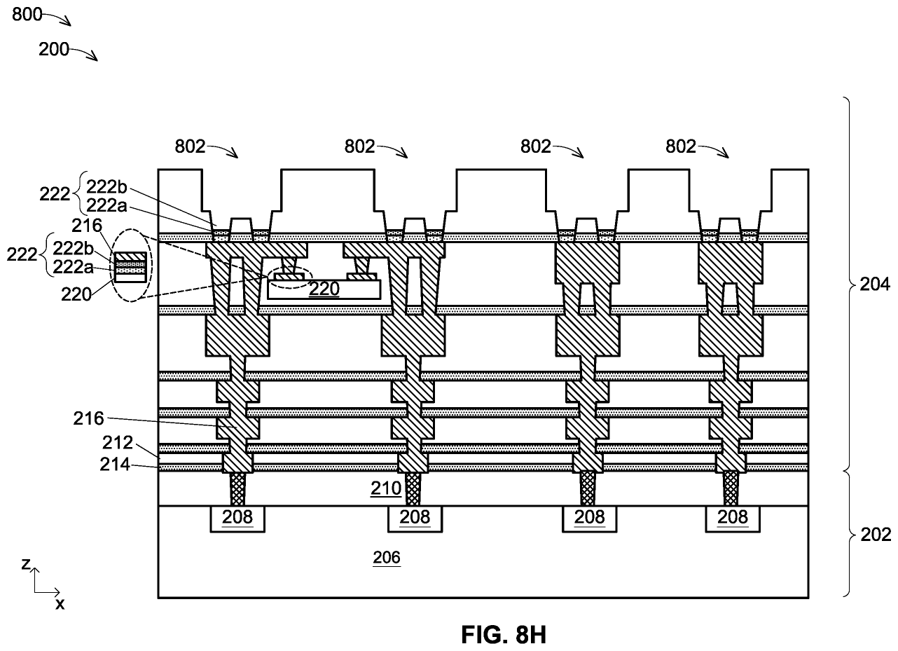

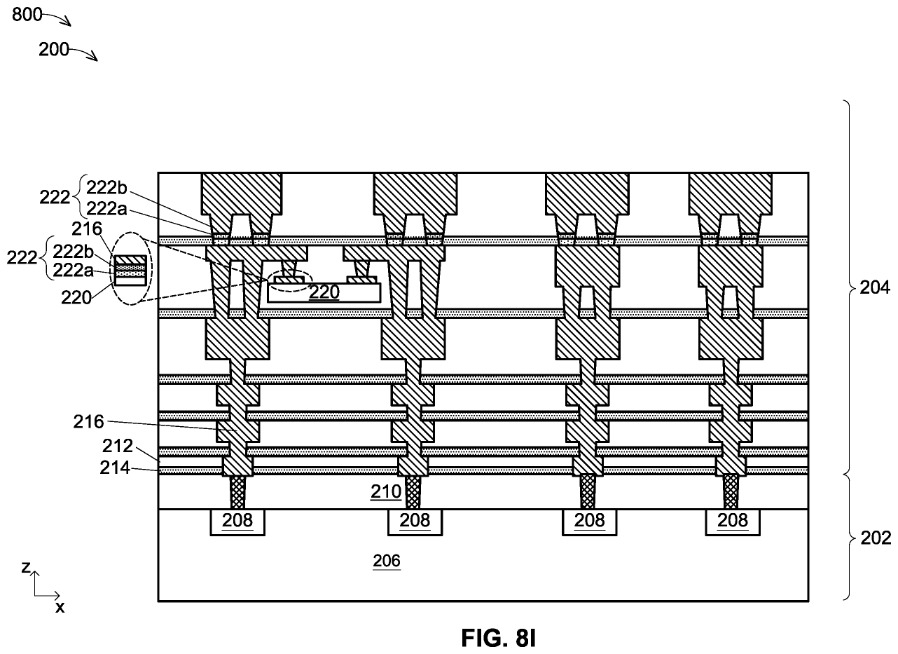

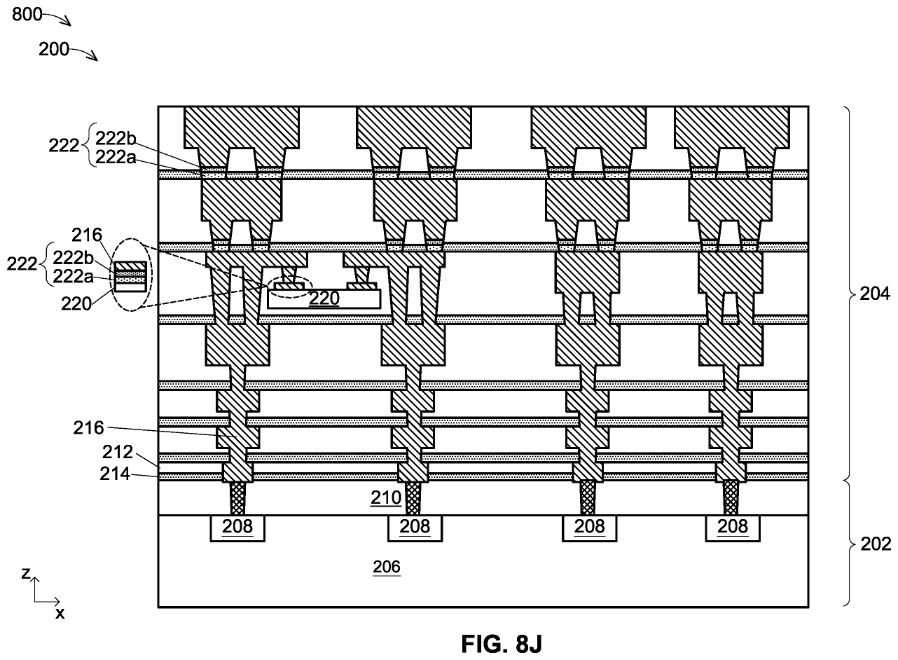

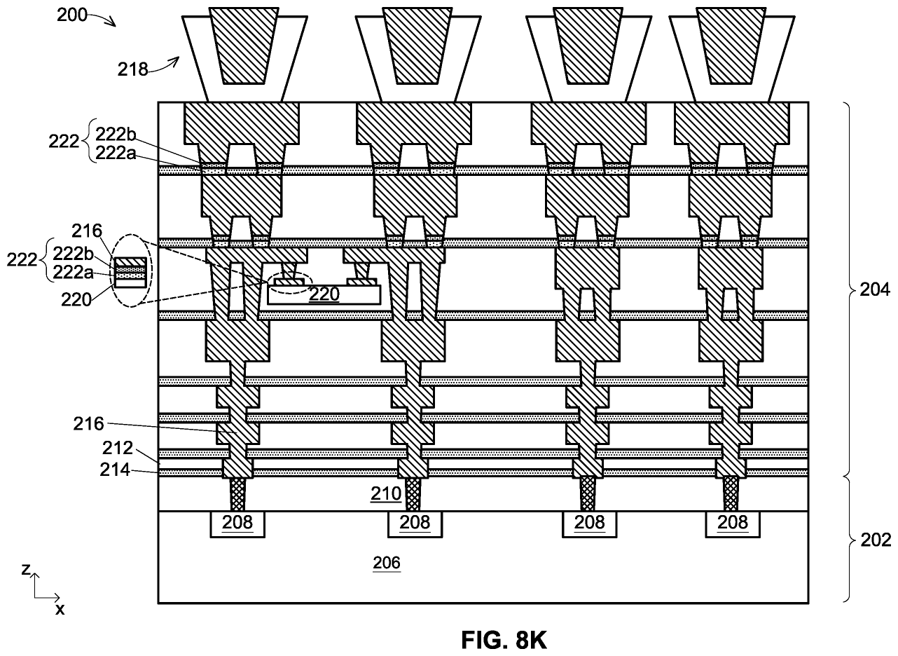

In some implementations, one or more of the semiconductor processing tools 102-112 and/or the wafer/die transport tool 114 may be used to perform one or more semiconductor processing operations described in connection with FIGS. 8A-8K, 9A, 9B, 10A-10N, 12, and/or 13, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

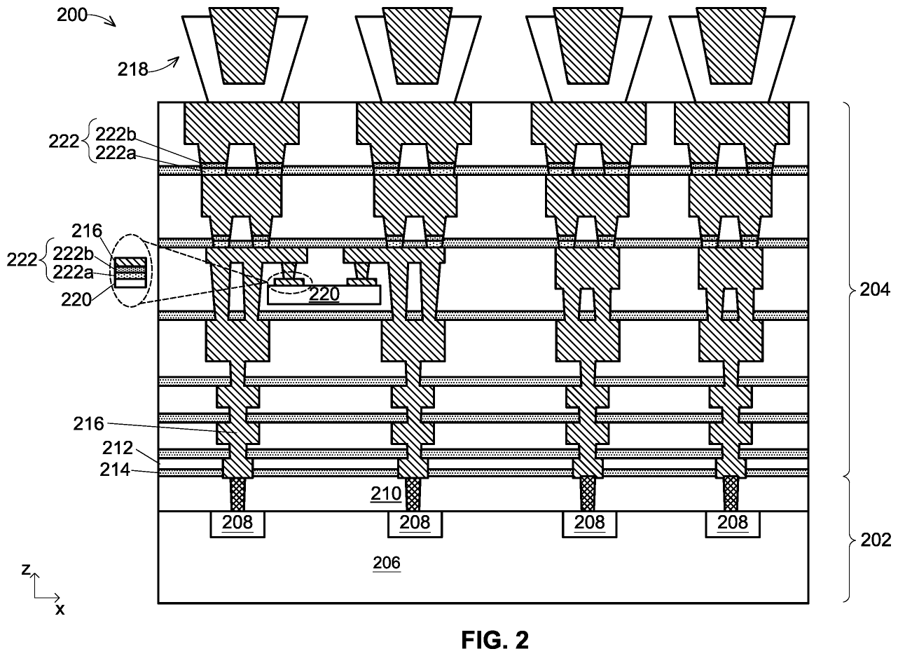

FIG. 2 is a diagram of an example semiconductor device 200 described herein. The semiconductor device 200 may include system on chip (SoC) device, a logic device such as a central processing unit (CPU) or a graphics processing unit (GPU), a memory device (e.g., a high bandwidth memory (HBM) device), and/or another type of semiconductor device.

As shown in FIG. 2, the semiconductor device 200 may include a device layer 202 and an interconnect structure 204 above the device layer 202 in a z-direction in the semiconductor device 200. The device layer 202 includes a substrate 206. The substrate 206 may correspond to a portion of a semiconductor wafer on which the semiconductor device 200 is formed. The substrate 206 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 206 may extend in an x-direction and/or in a y-direction in the semiconductor device 200.

Semiconductor devices 208 may be included in and/or on the substrate 206 in the device layer 202 of the semiconductor device 200. The semiconductor devices 208 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

A dielectric layer 210 is included over the substrate 206. The dielectric layer 210 includes an interlayer dielectric (ILD) layer, an etch stop layer (ESL), and/or another type of dielectric layer. The dielectric layer 210 includes dielectric material(s) that enable various portions of the substrate 206 and/or the semiconductor devices 208 to be selectively etched or protected from etching, and/or to electrically isolate the semiconductor devices 208 in the device layer 202. The dielectric layer 210 includes a silicon nitride (SiₓN_{y}), an oxide (e.g., a silicon oxide (SiOₓ) and/or another oxide material), and/or another type of dielectric material. The dielectric layer 210 may extend in the x-direction and/or in a y-direction in the semiconductor device 200.

The interconnect structure 204 of the semiconductor device 200 is included above the substrate 206 and above the semiconductor devices 208 in the z-direction in the semiconductor device 200. The interconnect structure 204 includes a plurality of dielectric layers that are arranged in a direction (e.g., the z-direction) that is approximately perpendicular to the substrate 206. The dielectric layers may include ILD layers 212 and ESLs 214 that are arranged in an alternating manner in the z-direction. The ILD layers 212 and the ESLs 214 may extend in the x-direction and/or in the y-direction in the semiconductor device 200.

The ILD layers 212 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 212 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 214 may each include a silicon nitride (SiₓN_{y}), silicon carbide (SiC), silicon oxynitride (SiON), and/or another suitable dielectric material. In some implementations, an ILD layer 212 and an ESL 214 include different dielectric materials to provide etch selectivity to enable various structures to be formed in the interconnect structure 204.

The interconnect structure 204 includes a plurality of conductive structures 216. The conductive structures 216 are electrically coupled and/or physically coupled with one or more of the semiconductor devices 208 in the device layer 202 and/or in the interconnect structure 204. The conductive structures 216 correspond to circuitry that enables signals and/or power to be provided to and/or from the semiconductor devices 208. The conductive structures 216 may include a combination of vias, trenches, contacts, plugs, interconnects, metallization layers, conductive traces, and/or other types of conductive structures. The conductive structures 216 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the conductive structures 216 and the ILD layers 212, and/or between the conductive structures 216 and the ESLs 214. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 216 of the interconnect structure 204 may be arranged in in a vertical manner (e.g., in the z-direction). In other words, a plurality of stacked conductive structures 216 extend between the device layer 202 and connection structures 218 above the interconnect structure 204 to facilitate electrical signals and/or power to be routed between the device layer 202 and the connection structures 218. The plurality of stacked conductive structures 216 may be referred to as M-layers. For example, a metal-0 (M0) layer may located at the bottom of the interconnect structure 204 and may be directly coupled with the device layer 202 (e.g., with the contacts or interconnects of the semiconductor devices 208 in the device layer 202), a metal-1 layer (M1) layer may be located above the M0 layer in the interconnect structure 204, a metal-2 layer (M2) layer may be located above the M1 layer, and so on. In some implementations, the interconnect structure 204 includes nine (9) stacked conductive structures 216 (e.g., M0-M8). In some implementations, the interconnect structure 204 includes another quantity of stacked conductive structures 216.

The connection structures 218 include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. The connection structures 218 enable the semiconductor device 200 to be attached to a semiconductor device package substrate (e.g., an interposer, a redistribution layer (RDL) structure, a printed circuit board (PCB)) and/or to another semiconductor device.

One or more semiconductor devices are also included in the interconnect structure 204 of the semiconductor device 200. For example, a non-volatile memory structure 220 is included in an ILD layer 212 of the interconnect structure 204. In other examples, a resistor, a capacitor, a radio frequency (RF) switch, an optical modulator, a waveguide, and/or another type of semiconductor device is included in the interconnect structure 204. The non-volatile memory structure 220 is electrically coupled and/or physically coupled with one or more conductive structures 216 in the interconnect structure 204.

In some implementations, the non-volatile memory structure 220 includes an FeRAM structure and/or another type of non-volatile memory structure that includes a ferroelectric field effect transistor (FeFET). The FeRAM structure (or non-volatile memory structure that includes the FeFET) includes a metal-oxide channel layer. In some implementations, the non-volatile memory structure 220 includes a non-volatile memory structure that includes a thin film transistor (TFT), a dynamic random access memory (DRAM) structure, a metal-ferroelectric-metal (MFM) memory structure, a metal-ferroelectric-metal-insulator (MFMI) memory structure, and/or another type of memory structure that includes a metal-oxide channel layer.

As further shown in FIG. 2, one or more hydrogen barrier layers 222 are included in the interconnect structure 204 of the semiconductor device 200. The hydrogen barrier layer(s) 222 minimize and/or prevent diffusion of hydrogen into one or more layers of the non-volatile memory structure 220. In some implementations, a hydrogen barrier layer 222 is included between vertically adjacent conductive structures 216 in the interconnect structure 204 (e.g., adjacent in the z-direction in the semiconductor device 200). In some implementations, a hydrogen barrier layer 222 is included between a conductive structure 216 and the non-volatile memory structure 220.

The hydrogen barrier layer(s) 222 may be included above the non-volatile memory structure 220 (e.g., the hydrogen barrier layer(s) 222 are located at a greater z-direction height in the semiconductor device 200 than the non-volatile memory structure 220). Hydrogen diffusion can occur during and/or as a result of one or more semiconductor processing operations that are performed after formation of the non-volatile memory structure 220. For example, hydrogen can diffuse into the conductive structures 216 from one or more ILD layers 212 and/or ESLs 214 that are formed above the non-volatile memory structure 220. As another example, a high pressure anneal (or another type of anneal operation) may be performed on the semiconductor device 200 after formation of the non-volatile memory structure 220 and/or after formation of one or more layers above the non-volatile memory structure. The high pressure anneal may involve the use of a hydrogen process gas, and hydrogen from the hydrogen process gas can diffuse through the conductive structures 216. Including the hydrogen barrier layer(s) 222 above the non-volatile memory structure 220 enables the hydrogen barrier layer(s) 222 to minimize and/or prevent diffusion of hydrogen downward into the non-volatile memory structure 220 through the conductive structures 216 that might otherwise result from these subsequent semiconductor processing operations.

A hydrogen barrier layer 222 may include a multiple-layer stack that includes a plurality of layers. For example, a hydrogen barrier layer 222 may include a hydrogen absorption layer 222a and a hydrogen blocking layer 222b over and/or on the hydrogen absorption layer 222a. In some implementations, a hydrogen barrier layer 222 includes only a hydrogen absorption layer 222a or only a hydrogen blocking layer 222b.

A hydrogen blocking layer 222b includes one or more materials that resist the diffusion of hydrogen by blocking hydrogen from diffusing into and through the hydrogen blocking layer 222b. Examples of such hydrogen blocking materials include various types of hydrogen blocking metal-containing materials and/or hydrogen blocking conductive metal nitrides, and/or hydrogen blocking dielectrics, among other examples. Examples of hydrogen blocking metals that can be used in the hydrogen blocking layer 222b include ruthenium (Ru), silver (Ag), aluminum (Al), titanium (Ti), gold (Au), platinum (Pt), cobalt (Co), iron (Fe), tin (Sn), and/or nickel (Ni), among other examples. Examples of hydrogen blocking conductive metal nitrides include titanium nitride (TiN), among other examples. Examples of hydrogen blocking dielectrics include aluminum oxide (AlₓO_{y} such as Al₂O₃), silicon nitride (SiₓN_{y} such as Si₃N₄), titanium oxide (TiOₓ such as TiO₂), and/or titanium carbide (TiC), among other examples.

A hydrogen absorption layer 222a includes one or more materials that resist the diffusion of hydrogen by absorbing the hydrogen before the hydrogen can pass through the hydrogen absorption layer 222a. Thus, hydrogen that passes through a hydrogen blocking layer 222b above a hydrogen absorption layer 222a may be absorbed by the hydrogen absorption layer 222a, thereby minimizing and/or preventing the hydrogen from passing through both the hydrogen blocking layer 222b and the hydrogen absorption layer 222a. Examples of hydrogen absorption materials that can be used in the hydrogen absorption layer 222a include one or more materials that have a high propensity of absorbing hydrogen. For example, the hydrogen absorption layer 222a may include one or more metal-oxide-containing materials and/or one or more metal-oxide semiconductor materials that tend to readily absorb hydrogen. Thus, the metal-oxide material(s) and/or the metal-oxide semiconductor material(s) of the hydrogen absorption layer 222a can absorb hydrogen before the hydrogen can diffuse into the non-volatile memory structure 220 and be absorbed by the metal-oxide material(s) and/or the metal-oxide semiconductor material(s) of the channel layer of the non-volatile memory structure 220. Examples of metal-oxide material(s) and/or metal-oxide semiconductor material(s) that may be included in a hydrogen absorption layer 222a include electrically conductive metal-oxide material(s) and/or electrically conductive metal-oxide semiconductor material(s) that contain one or more metals such as titanium (Ti), zirconium (Zr), vanadium (V), copper (Cu), tungsten (W), thorium (Th), tin (Sn), indium (In), zinc (Zn), and/or palladium (Pd), among other examples. For example, the hydrogen absorption layer 222a may include highly nitrogenized indium gallium zinc oxide (InGaZnO or IGZO), indium gallium oxide (InGaO or IGO), indium zinc oxide (InZnO or IZO), indium oxide (InO), zinc tin oxide (ZnSnO or ZSO), gallium zinc oxide (GaZnO or GZO), indium tin oxide (InSnO or ISO), and/or zinc oxide (ZnO), among other examples.

As indicated above, FIG. 2 is provided as an example. Other examples may differ from what is described with regard to FIG. 2.

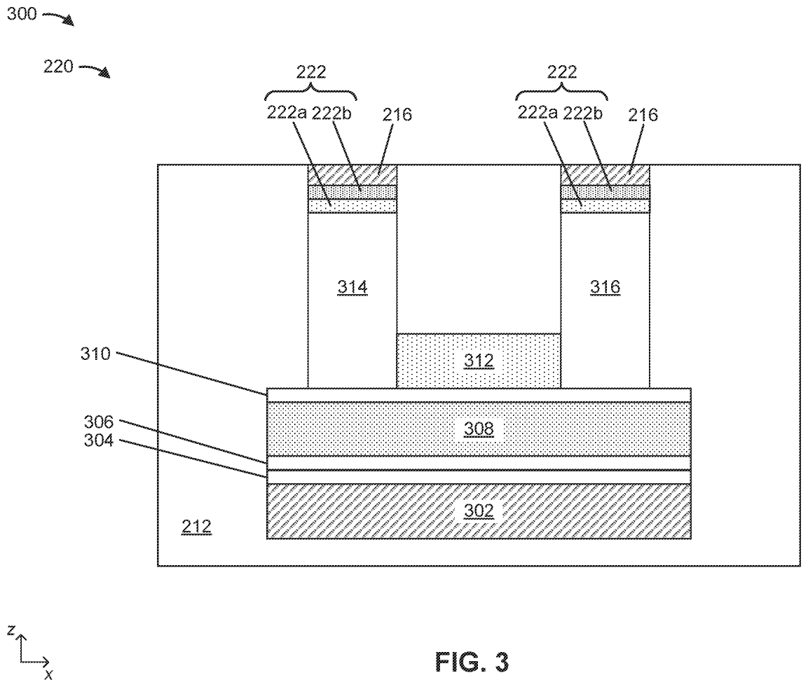

FIG. 3 is a diagram of an example implementation 300 of a non-volatile memory structure 220 described herein. As described herein, one or more hydrogen barrier layers 222 are included between the non-volatile memory structure 220 and one or more conductive structures 216 in the interconnect structure 204 of the semiconductor device 200. The hydrogen barrier layer(s) 222 are included above the non-volatile memory structure 220 to enable the hydrogen barrier layer(s) 222 to minimize and/or prevent diffusion of hydrogen downward into the non-volatile memory structure 220 through the conductive structures 216.

As shown in FIG. 3, the non-volatile memory structure 220 may be included in an ILD layer 212 of the interconnect structure 204 of the semiconductor device 200. The non-volatile memory structure 220 may include a bottom gate electrode 302. The bottom gate electrode 302 may also be referred to as a buried electrode and may be the gate structure of the non-volatile memory structure 220. The bottom gate electrode 302 may be electrically coupled with a word line of a non-volatile memory array in which the non-volatile memory structure 220 is included. The bottom gate electrode 302 may include one or more electrically conductive metal materials having a relatively low coefficient of thermal expansion (CTE). Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), and/or an alloy thereof, among other examples.

The non-volatile memory structure 220 may include an interfacial layer 304 over and/or on the bottom gate electrode 302. The interfacial layer 304 may include an oxide-containing material that is configured to reduce stress inducement in the non-volatile memory structure 220 from thermal expansion and/or contraction, and/or from other types of stress experienced by the non-volatile memory structure 220. Examples of oxide-containing materials for the interfacial layer 304 include tantalum pentoxide (Ta₂O₅), potassium oxide (K₂O), rubidium oxide (Rb₂O), strontium oxide (SrO), barium oxide (BaO), zirconium oxide (ZrO or ZrO₂), yttrium oxide (Y₂O₃), hafnium oxide (HfO₂), hafnium silicon oxide (HfSiO₂), amorphous vanadium oxide (α-V₂O₃), amorphous chromium oxide (α-Cr₂O₃), amorphous gallium oxide (α-Ga₂O₃), amorphous iron oxide (α-Fe₂O₃), amorphous titanium oxide (α-Ti₂O₃), amorphous indium oxide (α-In₂O₃), yttrium aluminum perovskite (YAlO₃ or YAP), bismuth oxide (Bi₂O₃), ytterbium oxide (Yb₂O₃), dysprosium oxide (Dy₂O₃), gadolinium oxide (Gd₂O₃), strontium titanium oxide (SrTiO₃) dysprosium scandium oxide (DyScO₃), terbium scandium oxide (TbScO₃), gadolinium scandium oxide (GdScO₃), neodymium scandium oxide (NdScO₃), neodymium gallium oxide (NdGaO₃), and/or tantalum lanthanum strontium aluminate (LaSrAlTaO₃ or LSAT), among other examples. In some implementations, the interfacial layer 304 includes a bi-layer epitaxial structure that includes lanthanum strontium manganese oxide (LaSrMnO₃ or LSMO) and SrTiO₃, LSMO and DyScO₃, LSMO and TbScO₃, LSMO and GdScO₃, LSMO and NdScO₃, LSMO and NdGaO₃, and/or LSMO and LSAT, among other examples. In some implementations, a thickness of the interfacial layer 304 is included in a range of approximately 0.5 nanometers to approximately 5 nanometers. However, other values for the range are within the scope of the present disclosure.

The non-volatile memory structure 220 may include a seed layer 306 over and/or on the interfacial layer 304. The seed layer 306 may provide a substrate on which a ferroelectric layer 308 of the non-volatile memory structure 220 is formed. The seed layer 306 may include a single layer structure or a multiple layer structure. The seed layer 306 may primarily have a cubic phase, a tetragonal phase, and/or an orthorhombic phase (e.g., where the cubic phase, the tetragonal phase, and/or the orthorhombic phase are greater than the monoclinic phase). The seed layer 306 may include one or more oxide materials, such as tantalum (Ta), tantalum pentoxide (Ta₂O₅), zirconium (Zr), zirconium oxide (ZrO or ZrO₂), yttrium oxide (Y₂O₃), hafnium (Hf), hafnium oxide (HfO₂), aluminum oxide (Al₂O₃), hafnium zirconium oxide (HfₓZr₁₋ₓO_{y}), and/or another oxide material. In some implementations, a thickness of the seed layer 306 is included in a range of approximately 0.1 nanometers to approximately 10 nanometers. However, other values for the range are within the scope of the present disclosure.

The ferroelectric layer 308 may be included over and/or on the seed layer 306. The ferroelectric layer 308 may include a ferroelectric material having oxygen vacancies and/or primarily including a cubic phase, a tetragonal phase, and/or an orthorhombic phase (e.g., where the cubic phase, the tetragonal phase, and/or the orthorhombic phase are greater than the monoclinic phase). Examples include hafnium oxide (e.g., HfO or HfO₂), zirconium oxide (e.g., ZrO₂), aluminum nitride (AlN), aluminum scandium nitride (e.g., AlScN), PBT (e.g., PbZrO₃), PZT (e.g., Pb[ZrxTi₁₋ₓ]O₃, (0≤x≤1)), PLZT (e.g., Pb₁₋ₓLaₓZr_{1-y}Ti_{y}O₃), barium titanate (e.g., BaTiO₃), lead titanate (e.g., PbTiO₃), lead metaniobate (e.g., PbNb₂O₆), lithium niobate (e.g., LiNbO₃), lithium tantalate (e.g., LiTaO₃), PMN (e.g., PbMg₁₋₃Nb_{2/3}O₃), PST (e.g., PbSc_{1/2}Ta_{1/2}O₃), SBT (e.g., SrBi₂Ta₂O₉), BNT (e.g., Bi_{1/2}Na_{1/2}TiO₃), and/or combinations thereof, among other examples. In some implementations, the ferroelectric material may include dopants such as scandium (Sc), lanthanum (La), calcium (Ca), barium (Ba), yttrium (Y), strontium (Sr), zirconium (Zr), silicon (Si), aluminum (Al), scandium (Sc), indium (In), and/or gadolinium (Gd), among other examples. For example, the ferroelectric material may include hafnium oxide doped with zirconium (e.g., Zr:HfO₂), hafnium oxide doped with silicon (e.g., Si:HfO₂), hafnium oxide doped with lanthanum (e.g., La:HfO₂), hafnium oxide doped with aluminum (e.g., Al:HfO₂), hafnium oxide doped with tantalum (Ta:HfO₂), hafnium oxide doped with scandium (e.g., Sc:HfO₂), hafnium oxide doped with yttrium (e.g., Y:HfO₂), hafnium oxide doped with strontium (e.g., Sr:HfO₂), hafnium oxide doped with indium (e.g., In:HfO₂), and/or hafnium oxide doped with gadolinium (e.g., Gd:HfO₂), among other examples. In some implementations, a thickness of the ferroelectric layer 308 is included in a range of approximately 0.1 nanometers to approximately 100 nanometers. However, other values for the range are within the scope of the present disclosure.

The non-volatile memory structure 220 may include a blocking layer 310 over and/or on the ferroelectric layer 308. The blocking layer 310 may include a combination of silicon (Si) and hafnium oxide (HfO₂). The blocking layer 310 may have a silicon to hafnium oxide ratio of greater than approximately 1:10. However, other values are within the scope of the present disclosure. Additionally and/or alternatively, the blocking layer 310 may include one or more of silicon (Si), magnesium (Mg), aluminum (Al), lanthanum (La), yttrium oxide (Y₂O₃), nitrogen (N), calcium (Ca), scandium (Sc), strontium (Sr), gadolinium (Gd), titanium nitride (TiN), tungsten carbonitride (WCN), tungsten nitride (WN), and/or tantalum nitride (TaN), among other examples. In some implementations, an oxygen to zirconium concentration or an oxygen to hafnium concentration at the interface between the blocking layer 310 and the ferroelectric layer 308 may be greater than or equal to approximately 1:1. However, other values are within the scope of the present disclosure. In some implementations, a thickness of the blocking layer 310 is included in a range of approximately 0.1 nanometers to approximately 10 nanometers. However, other values for the range are within the scope of the present disclosure.

The non-volatile memory structure 220 may include a metal-oxide channel layer 312 over and/or on the blocking layer 310. The metal-oxide channel layer 312 may include one or more metal-oxide materials or metal-oxide semiconductor materials. Examples include indium gallium zinc oxide (InGaZnO or IGZO), amorphous IGZO (α-IGZO), gallium zinc oxide (GaZnO or GZO), tin gallium zinc oxide (SnGaZnO or SGZO), silicon (Si), germanium (Ge), silicon germanium (SiGe), a silicon-germanium-carbon alloy (SiGeC), gallium arsenide (GaAs), indium phosphide (InP), gallium phosphate (GaP), gallium nitride (GaN), gallium antimony (GaSb), aluminum arsenide (AlAs), indium arsenide (InAs), indium antimony (InSb), aluminum gallium arsenide (AlGaAs), gallium indium arsenide (GaInAs), gallium indium phosphate (GaInP), indium aluminum arsenide (InAlAs), aluminum indium gallium phosephate (AlInGaP), cadmium sulfide (CdS), cadmium selenide (CdSe), zinc sulfied (ZnS), zinc selenide (ZnSe), zinc telluride (ZnTe), lead sulfide (PbS), led telluride (PbTe), mercury telluride (HgTe), indium gallium tin oxide (InGaSnO), and/or indium gallium tin zinc oxide (InGASnZnO), among other examples. In some implementations, hafnium (Hf), zirconium (Zr), titanium (Ti), aluminum (Al), tantalum (Ta), strontium (Sr), barium (Ba), scandium (Sc), magnesium (Mg), lanthanum (La), and/or gadolinium (Gd) may be used instead of gallium in the metal-oxide channel layer 312 to achieve a lower concentration of oxygen vacancies and/or to achieve lower surface states. Additionally and/or alternatively, a II-VI compound semiconductor material and/or a III-V compound semiconductor material may be used for the channel layer of the non-volatile memory structure 220. In some implementations, a thickness of the metal-oxide channel layer 312 is included in a range of approximately 1 nanometer to approximately 100 nanometers. However, other values for the range are within the scope of the present disclosure.

The non-volatile memory structure 220 may include source/drain electrodes 314 and 316 above and/or on the blocking layer 310. A source/drain electrode may refer to a source region or a drain electrode, individually or collectively, dependent upon the context. In some implementations, the metal-oxide channel layer 312 is located between the source/drain electrodes 314 and 316, as shown in the example implementation 300 in FIG. 3. In some implementations, the source/drain electrodes 314 and 316 are included on the metal-oxide channel layer 312, and the metal-oxide channel layer 312 is located between the blocking layer 310 and the source/drain electrodes 314 and 316. The source/drain electrodes 314 and 316 may each include one or more metal materials, such as aluminum (Al), titanium (Ti), tantalum (Ta), tungsten (W), ruthenium (Ru), cobalt (Co), copper (Cu), and/or gold (Au), among other examples.

The bottom gate electrode 302, the ferroelectric layer 308, the metal-oxide channel layer 312, and the source/drain electrodes 314 and 316 may correspond to an FeFET of the non-volatile memory structure 220. The source/drain electrodes 314 and 316 may each be included in ILD layer 212. In some implementations, a height or a thickness of the source/drain electrodes 314 and/or 316 may be included in a range of approximately 10 nanometers to approximately 600 nanometers. However, other values for the range are within the scope of the present disclosure.

To transition the non-volatile memory structure 220 to a programmed state, a first gate voltage (e.g., a positive gate voltage +V_{G}) may be applied to the bottom gate electrode 302. This causes electron charge carriers in electron/hole pairs in the ferroelectric layer 308 to be biased toward the bottom gate electrode 302. A 0 voltage (0 V) may be applied to the source/drain electrode 314, and the source/drain electrode 316 may be grounded. This causes the metal-oxide channel layer 312 to be in a non-conductive state, thereby causing hole charge carriers in the electron/hole pairs of the ferroelectric layer 308 to be biased toward the metal-oxide channel layer 312.

To transition the non-volatile memory structure 220 to an erased state, a second gate voltage (e.g., a negative gate voltage −V_{G}) may be applied to the bottom gate electrode 302. A 0 voltage (0 V) may be applied to the source/drain electrode 314, and the source/drain electrode 316 may be grounded. This causes the metal-oxide channel layer 312 to be in a conductive state. This causes the hole charge carriers in electron/hole pairs in the ferroelectric layer 308 to be biased toward the bottom gate electrode 302, and causes the electron charge carriers in the electron/hole pairs of the ferroelectric layer 308 to be biased toward the metal-oxide channel layer 312.

The source/drain electrodes 314 and 316 may each be electrically coupled with a conductive structure 216 in the interconnect structure 204 of the semiconductor device 200. This enables electrical inputs (e.g., voltages, electrical currents) to be applied to the source/drain electrode 314 and/or the source/drain electrode 316, and/or enables the source/drain electrode 314 and/or the source/drain electrode 316 to be electrically grounded.

As further shown in FIG. 3, a hydrogen barrier layer 222 may be included between the source/drain electrode 314 and a conductive structure 216, and/or a hydrogen barrier layer 222 may be included between the source/drain electrode 316 and a conductive structure 216. For example, a hydrogen absorption layer 222a of a hydrogen barrier layer 222 may be included on the source/drain electrode 314, a hydrogen blocking layer 222b of a hydrogen barrier layer 222 may be included on the hydrogen absorption layer 222a, and a conductive structure 216 may be included on the hydrogen blocking layer 222b. As another example, a hydrogen absorption layer 222a of a hydrogen barrier layer 222 may be included on the source/drain electrode 316, a hydrogen blocking layer 222b of a hydrogen barrier layer 222 may be included on the hydrogen absorption layer 222a, and a conductive structure 216 may be included on the hydrogen blocking layer 222b. In some implementations, a hydrogen absorption layer 222a is omitted from a hydrogen barrier layer 222, and a hydrogen blocking layer 222b of the hydrogen barrier layer 222 is included on the source/drain electrode 314 and/or on the source/drain electrode 316. In some implementations, a hydrogen absorption layer 222a is omitted from a hydrogen barrier layer 222, and a conductive structure 216 is included on a hydrogen blocking layer 222b of the hydrogen barrier layer 222.

As indicated above, FIG. 3 is provided as an example. Other examples may differ from what is described with regard to FIG. 3.

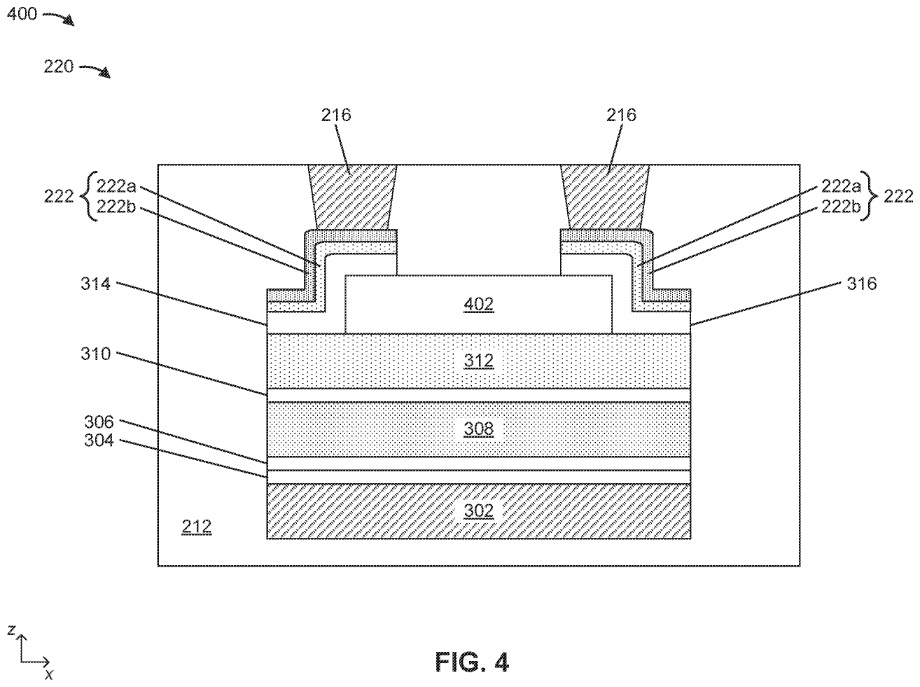

FIG. 4 is a diagram of an example implementation 400 of a non-volatile memory structure 220 described herein. The example implementation 400 of the non-volatile memory structure 220 includes a similar combination and arrangement of layers and/or structures as the example implementation 400 of the non-volatile memory structure 220. For example, the example implementation 400 of the non-volatile memory structure 220 includes a bottom gate electrode 302, an interfacial layer 304, a seed layer 306, a ferroelectric layer 308, a blocking layer 310, a metal-oxide channel layer 312, and source/drain electrodes 314 and 316. Moreover, hydrogen barrier layers 222 (including a hydrogen absorption layer 222a and/or a hydrogen blocking layer 222b) may be included between the source/drain electrode 314 and a conductive structure 216 and/or between the source/drain electrode 316 and a conductive structure 216.

In addition, the example implementation 400 of the non-volatile memory structure 220 includes a spacer 402 between the source/drain electrodes 314 and 316. The spacer 402 includes one or more dielectric materials such as a silicon oxide (SiOₓ), a silicon nitride (SiₓN_{y}), silicon carbide (SiC), silicon oxynitride (SiON), and/or another suitable dielectric material. The spacer 402 may provide electrical isolation between the source/drain electrodes 314 and 316, as well as may provide a pedestal on which the source/drain electrodes 314 and 316 are formed. The source/drain electrodes 314 and 316 are included on portions of the top surface of the metal-oxide channel layer 312, on opposing sidewalls of the spacer 402, and/or on portions of the top surface of the spacer 402. The hydrogen barrier layers 222 (including a hydrogen absorption layer 222a and/or a hydrogen blocking layer 222b) conform to the shapes and/or profiles of the source/drain electrodes 314 and 316.

As indicated above, FIG. 4 is provided as an example. Other examples may differ from what is described with regard to FIG. 4.

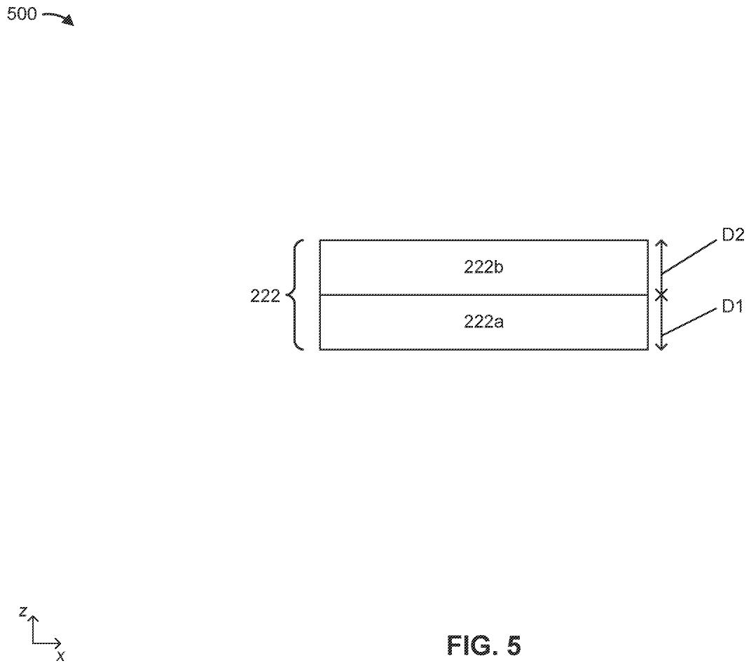

da diagram of an example implementation 500 of a hydrogen barrier layer 222 described herein. As shown in FIG. 5, the hydrogen barrier layer 222 may include a hydrogen absorption layer 222a and a hydrogen blocking layer 222b on the hydrogen absorption layer 222a.

The hydrogen absorption layer 222a has a dimension D1 corresponding to a z-direction thickness of the hydrogen absorption layer 222a. In some implementations, the dimension D1 is included in a range of approximately 10 angstroms to approximately 1000 nanometers. If the dimension D1 is less than approximately 10 angstroms, the hydrogen absorption layer 222a may not provide sufficient hydrogen absorption in order to prevent hydrogen absorption and charge carrier concentration in the metal-oxide channel layer 312 of the non-volatile memory structure 220. Values for the dimension D1 greater than approximately 1000 nanometers may result in high contact resistance between the non-volatile memory structure 220 and a conductive structure 216 (and/or between conductive structures 216) that results in increased line resistance-capacitance (RC) delay in the semiconductor device 200. If the dimension D1 is within the range of approximately 10 angstroms to approximately 1000 nanometers, the hydrogen absorption layer 222a may be sufficiently thick to effectively absorb hydrogen in the semiconductor device 200, and a low RC delay may be achieved in the semiconductor device 200. However, other values for the dimension D1, and ranges other than approximately 10 angstroms to approximately 1000 nanometers, are within the scope of the present disclosure.

The hydrogen blocking layer 222b has a dimension D2 corresponding to a z-direction thickness of the hydrogen blocking layer 222b. In some implementations, the dimension D2 is included in a range of approximately 10 angstroms to approximately 1000 nanometers. If the dimension D2 is less than approximately 10 angstroms, the hydrogen blocking layer 222b may not provide sufficient hydrogen diffusion blocking in order to prevent hydrogen absorption and charge carrier concentration in the metal-oxide channel layer 312 of the non-volatile memory structure 220. Values for the dimension D2 greater than approximately 1000 nanometers may result in high contact resistance between the non-volatile memory structure 220 and a conductive structure 216 (and/or between conductive structures 216) that results in increased line RC delay in the semiconductor device 200. If the dimension D2 is within the range of approximately 10 angstroms to approximately 1000 nanometers, the hydrogen blocking layer 222b may be sufficiently thick to effectively block hydrogen diffusion in the semiconductor device 200, and a low RC delay may be achieved in the semiconductor device 200. However, other values for the dimension D2, and ranges other than approximately 10 angstroms to approximately 1000 nanometers, are within the scope of the present disclosure.

As indicated above, FIG. 5 is provided as an example. Other examples may differ from what is described with regard to FIG. 5.

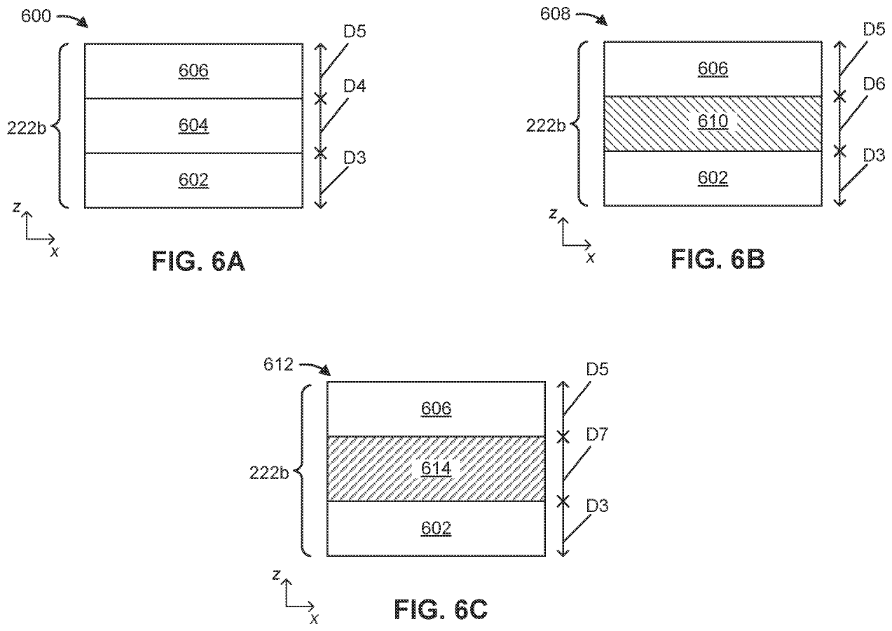

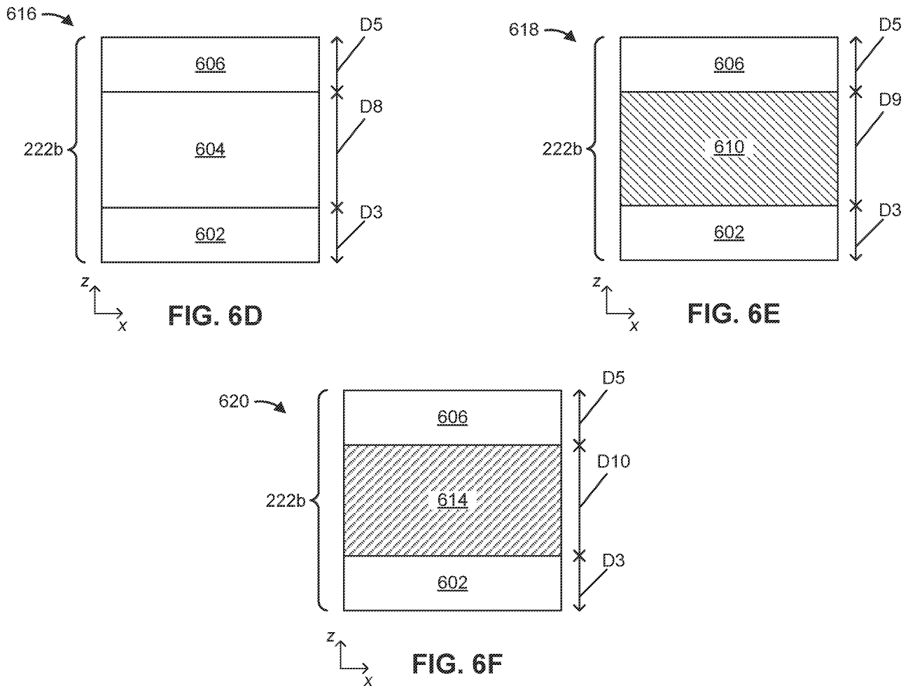

FIGS. 6A-6F are diagrams of example implementations of hydrogen blocking layers 222b described herein. In some implementations, a hydrogen blocking layer 222b includes a single-layer structure, such as a layer of ruthenium (Ru) or a layer of titanium (Ti), among other examples. The example implementations of hydrogen blocking layers 222b illustrated and described in connection with FIGS. 6A-6F include multiple-layer stacks in which the hydrogen blocking layers 222b include a plurality of layers. Including a plurality of layers in a hydrogen blocking layer 222b enables the hydrogen blocking properties of the hydrogen blocking layer 222b to be tuned for particular types of materials and/or thicknesses for the hydrogen blocking layer 222b.

As shown in FIG. 6A, an example implementation 600 of a hydrogen blocking layer 222b includes a plurality of titanium nitride (TiN) layers, such as a titanium nitride layer 602, a titanium nitride layer 604 on the titanium nitride layer 602, and a titanium nitride layer 606 on the titanium nitride layer 604. Thus, the titanium nitride layers 602-606 are arranged in the z-direction in the semiconductor device 200. The titanium nitride layer 602 has a dimension D3 corresponding to a z-direction thickness of the titanium nitride layer 602. The titanium nitride layer 604 has a dimension D4 corresponding to a z-direction thickness of the titanium nitride layer 604. The titanium nitride layer 606 has a dimension D5 corresponding to a z-direction thickness of the titanium nitride layer 606. In the example implementation 600, the dimension D3, the dimension D4, and the dimension D5 are approximately equal. In some implementations, the dimension D3, the dimension D4, and the dimension D5 are each included in a range of approximately 150 angstroms to approximately 250 angstroms. However, other values for the range are within the scope of the present disclosure.

As shown in FIG. 6B, an example implementation 608 of a hydrogen blocking layer 222b includes the titanium nitride layer 602, a titanium (Ti) layer 610 (e.g., a metal layer) on the titanium nitride layer 602, and the titanium nitride layer 606 on the titanium layer 610. Thus, the titanium nitride layer 602, the titanium layer 610, and the titanium nitride layer 606 are arranged in the z-direction in the semiconductor device 200. The titanium nitride layer 602 has the dimension D3 corresponding to the z-direction thickness of the titanium nitride layer 602. The titanium layer 610 has a dimension D6 corresponding to a z-direction thickness of the titanium layer 610. The titanium nitride layer 606 has the dimension D5 corresponding to the z-direction thickness of the titanium nitride layer 606. In the example implementation 608, the dimension D3, the dimension D6, and the dimension D5 are approximately equal. In some implementations, the dimension D3, the dimension D6, and the dimension D5 are each included in a range of approximately 150 angstroms to approximately 250 angstroms. However, other values for the range are within the scope of the present disclosure.

As shown in FIG. 6C, an example implementation 612 of a hydrogen blocking layer 222b includes the titanium nitride layer 602, a ruthenium (Ru) layer 614 (e.g., a metal layer) on the titanium nitride layer 602, and the titanium nitride layer 606 on the ruthenium layer 614. Thus, the titanium nitride layer 602, the ruthenium layer 614, and the titanium nitride layer 606 are arranged in the z-direction in the semiconductor device 200. The titanium nitride layer 602 has the dimension D3 corresponding to the z-direction thickness of the titanium nitride layer 602. The ruthenium layer 614 has a dimension D7 corresponding to a z-direction thickness of the ruthenium layer 614. The titanium nitride layer 606 has the dimension D5 corresponding to the z-direction thickness of the titanium nitride layer 606. In the example implementation 612, the dimension D3 and the dimension D5 are approximately equal, and are each included in a range of approximately 150 angstroms to approximately 250 angstroms. However, other values for the range are within the scope of the present disclosure. The dimension D7 is greater than the dimension D3 and the dimension D5. For example, the dimension D7 may be included in a range of approximately 210 angstroms to approximately 290 angstroms. However, other values for the range are within the scope of the present disclosure.

As shown in FIG. 6D, an example implementation 616 of a hydrogen blocking layer 222b includes the titanium nitride layers 602-606, similar to the example implementation 600. However, in the example implementation 616, the titanium nitride layer 604 has a dimension D8 corresponding to a z-direction thickness of the titanium nitride layer 604, and the dimension D8 is greater than the dimension D3 and the dimension D5. In some implementations, the dimension D8 is included in a range of approximately 550 angstroms to approximately 650 angstroms. However, other values for the range are within the scope of the present disclosure. In some implementations, a ratio of the dimension D8 to the dimension D3, and of the dimension D8 to the dimension D5, is included in a range of approximately 2:1 to approximately 4:1. However, other values for the range are within the scope of the present disclosure.

As shown in FIG. 6E, an example implementation 618 of a hydrogen blocking layer 222b includes the titanium nitride layer 602, the titanium layer 610, and the titanium nitride layer 606, similar to the example implementation 608. However, in the example implementation 618, the titanium 610 has a dimension D9 corresponding to a z-direction thickness of the titanium layer 610, and the dimension D9 is greater than the dimension D3 and the dimension D5. In some implementations, the dimension D9 is included in a range of approximately 550 angstroms to approximately 650 angstroms. However, other values for the range are within the scope of the present disclosure. In some implementations, a ratio of the dimension D9 to the dimension D3, and of the dimension D9 to the dimension D5, is included in a range of approximately 2:1 to approximately 4:1. However, other values for the range are within the scope of the present disclosure.

As shown in FIG. 6F, an example implementation 620 of a hydrogen blocking layer 222b includes the titanium nitride layer 602, the ruthenium layer 614, and the titanium nitride layer 606, similar to the example implementation 612. However, in the example implementation 620, the ruthenium layer 614 has a dimension D10 corresponding to a z-direction thickness of the ruthenium layer 614, and the dimension D10 is greater than the dimension D3 and the dimension D5. In some implementations, the dimension D10 is included in a range of approximately 430 angstroms to approximately 530 angstroms. However, other values for the range are within the scope of the present disclosure. In some implementations, a ratio of the dimension D10 to the dimension D3, and of the dimension D10 to the dimension D5, is included in a range of approximately 1.75:1 to approximately 3.5:1. However, other values for the range are within the scope of the present disclosure.

As indicated above, FIGS. 6A-6F are provided as examples. Other examples may differ from what is described with regard to FIGS. 6A-6F.

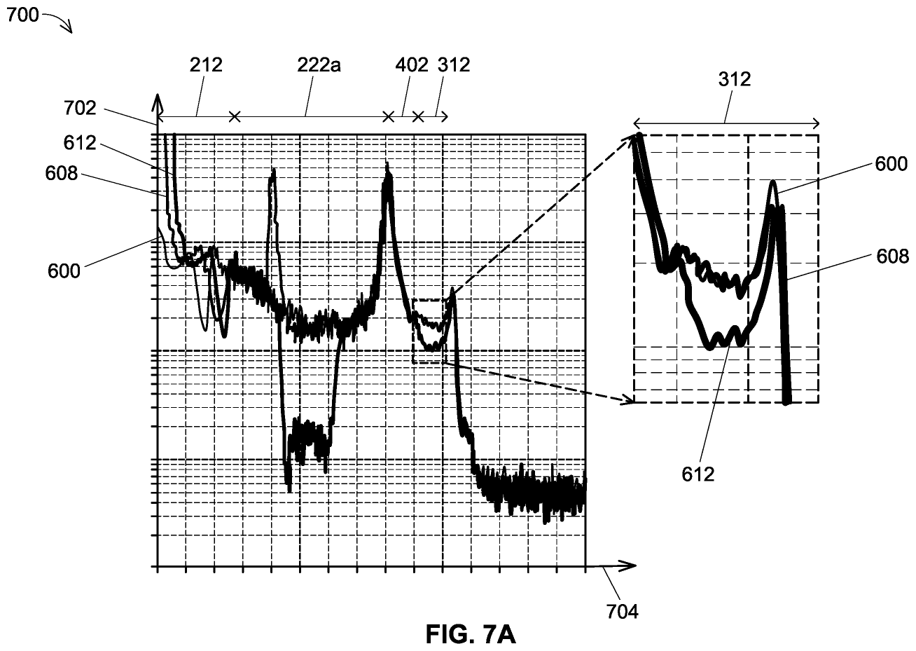

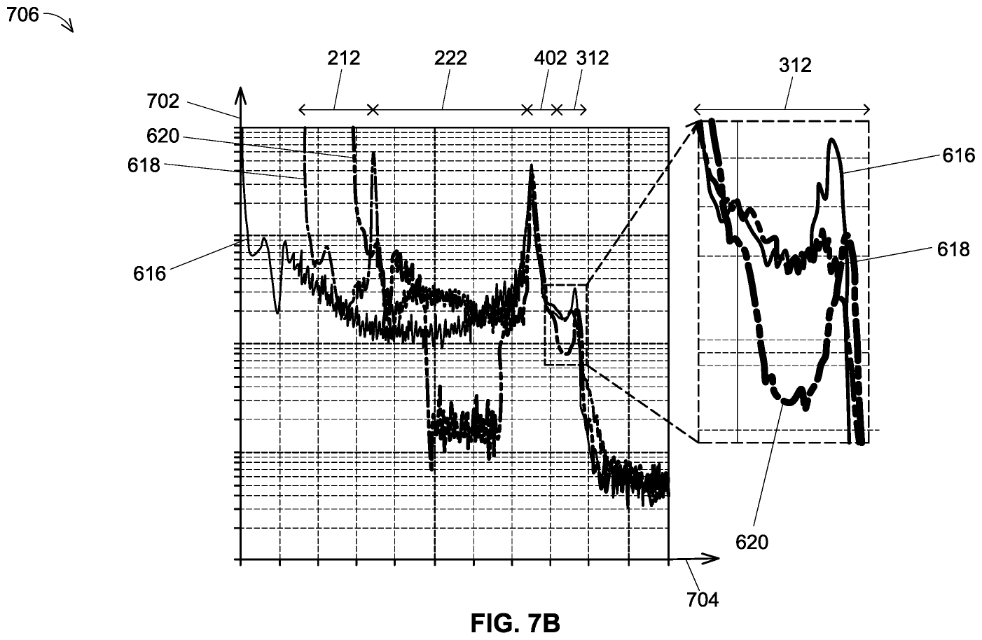

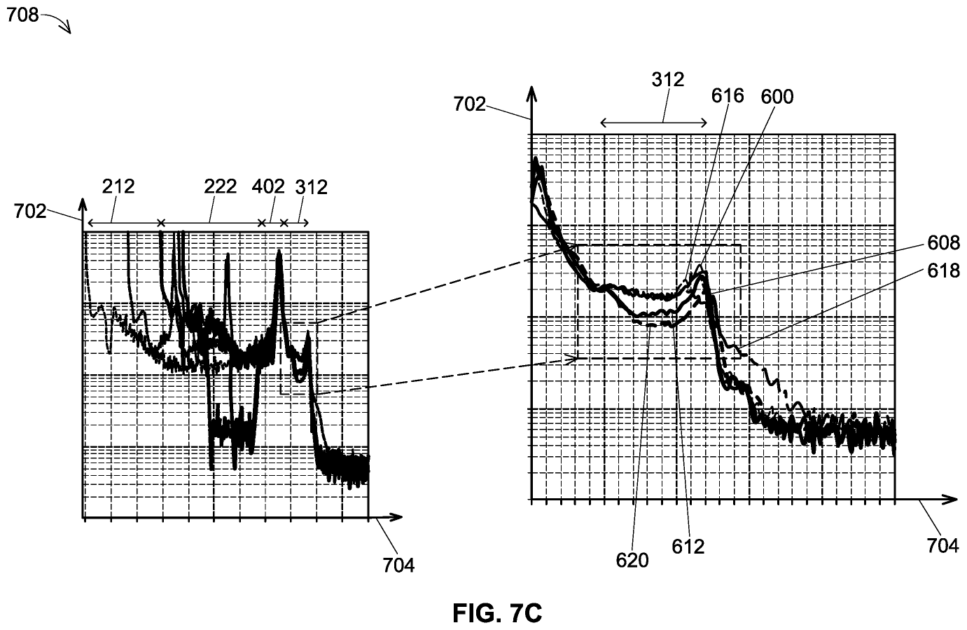

FIGS. 7A-7C are diagrams of example hydrogen concentrations in the semiconductor device 200 for the example implementations of a hydrogen blocking layer 222b illustrated and described in connection with FIGS. 6A-6F. FIG. 7A is an example 700 of hydrogen concentration 702 as a function of depth 704 in the semiconductor device 200 for hydrogen blocking layers 222b having different layer arrangements. For example, the example 700 includes hydrogen concentrations 702 for the example implementation 602 of a hydrogen blocking layer 222b, the example implementation 608 of a hydrogen blocking layer 222b, and the example implementation 612 of a hydrogen blocking layer 222b. The hydrogen concentrations 702 are shown in the ILD layer 212 above the non-volatile memory structure 220, the hydrogen blocking layers 222b, the spacer 402, and the metal-oxide channel layer 312.

In the example 700, the hydrogen concentrations 702 for each of the example implementations 600, 608, and 612 of the hydrogen blocking layer 222b result in blocking of hydrogen diffusion from the ILD layer 212 into the metal-oxide channel layer 312, as indicated by a lesser hydrogen concentration 702 in the metal-oxide channel layer 312 than in the ILD layer 212. The hydrogen concentration 702 spikes near the top of the titanium layer 610 in the example implementation 608 of the hydrogen blocking layer 222b in that the titanium layer 610 also absorbs hydrogen in addition to blocking the diffusion of hydrogen. The ruthenium layer 614 in the example implementation 612 of the hydrogen blocking layer 222b absorbs less hydrogen than the titanium layer 610 and the titanium nitride layer 604 in the example implementation 600 of the hydrogen blocking layer 222b. Thus, the hydrogen concentration 702 in the example implementation 612 of the hydrogen blocking layer 222b is less than the hydrogen concentration 702 in the example implementations 600 and 608 of the hydrogen blocking layers 222b.

FIG. 7B is an example 706 of hydrogen concentrations 702 for the example implementation 616 of a hydrogen blocking layer 222b, the example implementation 618 of a hydrogen blocking layer 222b, and the example implementation 620 of a hydrogen blocking layer 222b. As shown in FIG. 7B, the example implementation 616 of a hydrogen blocking layer 222b, the example implementation 618 of a hydrogen blocking layer 222b, and the example implementation 620 of a hydrogen blocking layer 222b have similar hydrogen blocking properties as the example implementation 600 of a hydrogen blocking layer 222b, the example implementation 608 of a hydrogen blocking layer 222b, and the example implementation 612 of a hydrogen blocking layer 222b, respectively.

As shown in an example 708 in FIG. 7C, the greater thickness of the titanium layer 610 in the example implementation 618 of the hydrogen blocking layer 222b may provide greater hydrogen blocking performance than the titanium layer 610 in the example implementation 608 of the hydrogen blocking layer 222b in that the hydrogen concentration 702 is less at greater depths 704 in the metal-oxide channel layer 312 for the example implementation 618 of the hydrogen blocking layer 222b than the example implementation 608 of the hydrogen blocking layer 222b. Similarly, the greater thickness of the ruthenium layer 614 in the example implementation 620 of the hydrogen blocking layer 222b may provide greater hydrogen blocking performance than the ruthenium layer 614 in the example implementation 612 of the hydrogen blocking layer 222b in that the hydrogen concentration 702 is less at greater depths 704 in the metal-oxide channel layer 312 for the example implementation 620 of the hydrogen blocking layer 222b than the example implementation 612 of the hydrogen blocking layer 222b.

As indicated above, FIGS. 7A-7C are provided as examples. Other examples may differ from what is described with regard to FIGS. 7A-7C.

FIGS. 8A-8K are diagrams of an example implementation 800 of forming the semiconductor device 200 described herein. In some implementations, one or more of the semiconductor processing operations described in connection with FIGS. 8A-8K may be performed using one or more of the semiconductor processing tools 102-112 described herein. In some implementations, one or more of the semiconductor processing operations described in connection with FIGS. 8A-8K may be performed using another type of semiconductor processing tool.

Turning to FIG. 8A, the substrate 206 is provided. The substrate 206 may be provided in the form of a semiconductor wafer such as a silicon (Si) wafer may be provided as an SOI wafer, and/or another type of semiconductor work piece.

As shown in FIG. 8B, the semiconductor devices 208 may be formed in and/or on the substrate 206 in the device layer 202 of the semiconductor device 200. One or more of the semiconductor processing tools 102-114 may be used to form one or more portions of the semiconductor devices 208. For example, a deposition tool 102 may be used to perform various deposition operations to deposit layers of the semiconductor devices 208, and/or to deposit photoresist layers for etching the substrate 206 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 206 and/or portions of the deposited layers to form the semiconductor devices 208. As another example, a planarization tool 110 may be used to planarize portions of the semiconductor devices 208. As another example, a plating tool 112 may be used to deposit metal structures and/or layers of the semiconductor devices 208.

As shown in FIG. 8C, a deposition tool 102 is used to deposit the dielectric layer 210 over and/or on the substrate 206 and over and/or on the semiconductor devices 208. A deposition tool 102 may be used to deposit the dielectric layer 210 using a PVD technique, an ALD technique, a CVD technique, an oxidation technique, another type of deposition technique described in connection with FIG. 1, and/or another suitable deposition technique. In some implementations, the planarization tool 110 may be used to planarize the dielectric layer 210 after the dielectric layer 210 is deposited.

As shown in FIG. 8D, a first portion of the interconnect structure 204 of the semiconductor device 200 is formed above the dielectric layer 210. A deposition tool 102 is used to deposit alternating layers of ILD layers 212 and ESLs 214 in the first portion of the interconnect structure 204 of the semiconductor device 200. In this way, the ILD layers 212 and ESLs 214 may be arranged in the z-direction in the semiconductor device 200. A deposition tool 102 may be used to deposit each of the ILD layers 212 and each of the ESLs 214 using a PVD technique, an ALD technique, a CVD technique, an oxidation technique, another type of deposition technique described in connection with FIG. 1, and/or another suitable deposition technique. In some implementations, the planarization tool 110 may be used to planarize the ILD layers 212 and/or the ESLs 214 after the ILD layers 212 and/or the ESLs 214 are deposited.

As further shown in FIG. 8D, a deposition tool 102, an exposure tool 104, a developer tool 106, an etch tool 108, a planarization tool 110, and/or a plating tool 112 are used to perform various operations to form the conductive structures 216 in the first portion of the interconnect structure 204 of the semiconductor device 200. The conductive structures 216 may be included in the ILD layers 212 and/or the ESLs 214, and may be electrically coupled with the semiconductor devices 208 in the device layer 202. In some implementations, the ILD layers 212, the ESLs 214, and the conductive structures 216 may built up in the z-direction in metallization layers. For example, a first ESL 214 and a first ILD layer 212 may be formed, recesses may be formed in first ESL 214 and/or in the first ILD layer 212, and first conductive structures 216 (e.g., an M0 metallization layer) may be formed in the recesses. A second ESL 214 and a second ILD layer 212 may be formed above the first ESL 214 and the first ILD layer 212, recesses may be formed in second ESL 214 and/or in the second ILD layer 212, and second conductive structures 216 (e.g., an M1 metallization layer) may be formed in the recesses. The remaining metallization layers of the first portion of the interconnect structure 204 may be formed in a similar manner.

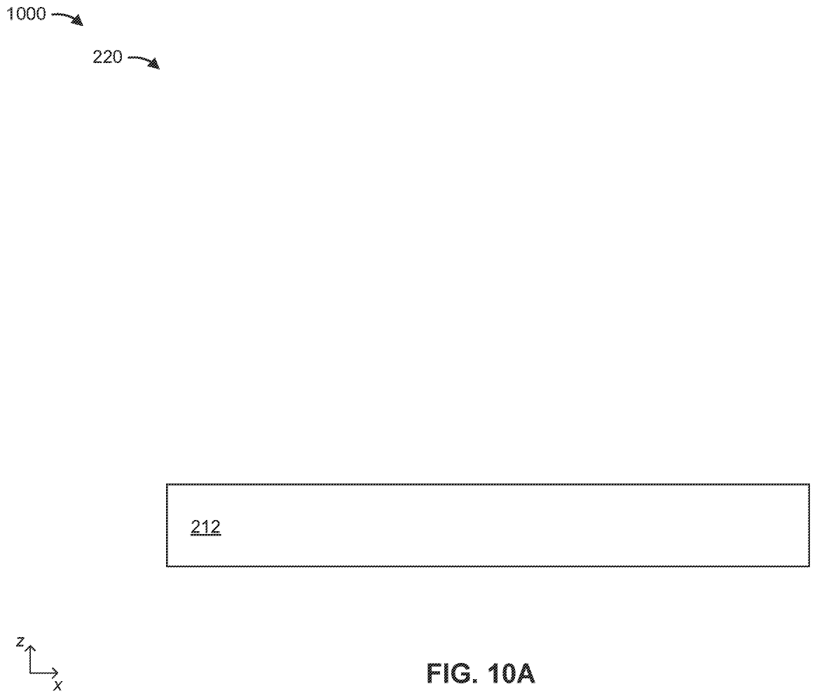

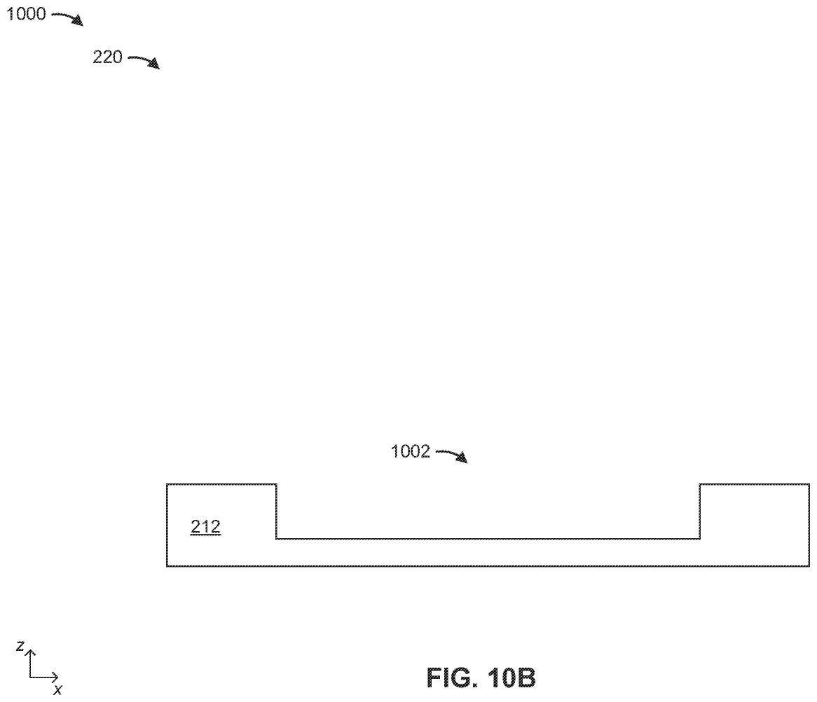

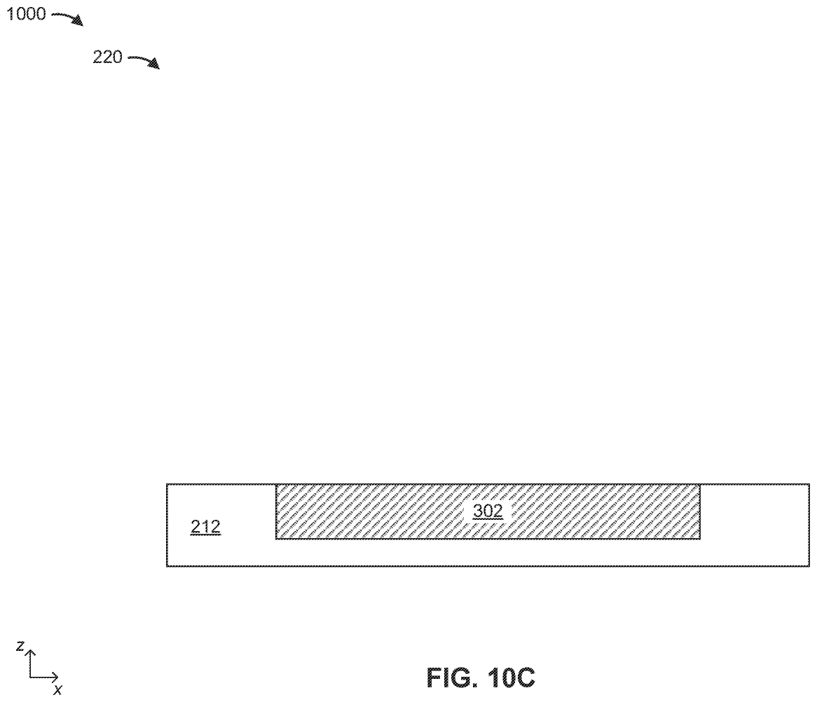

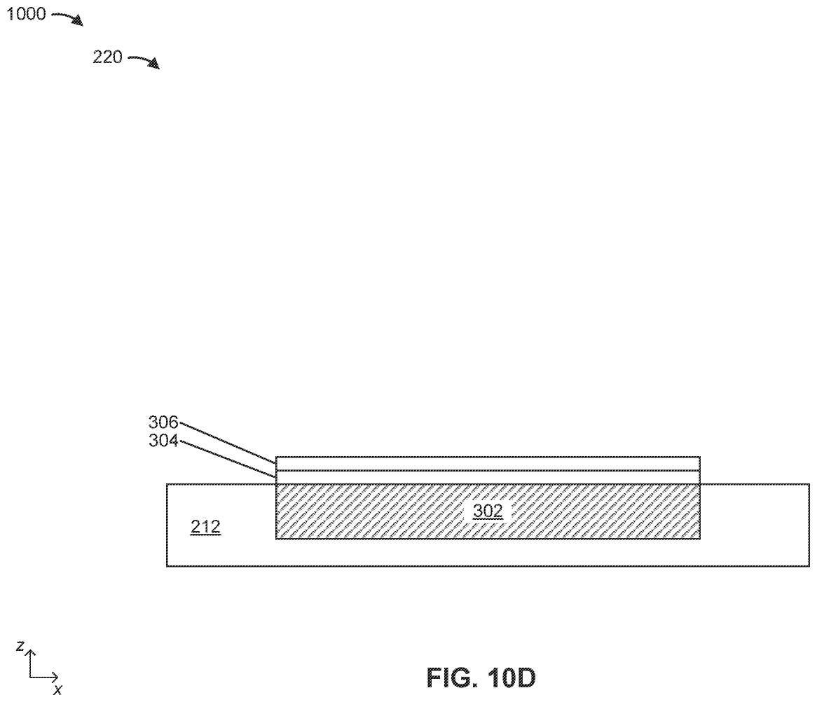

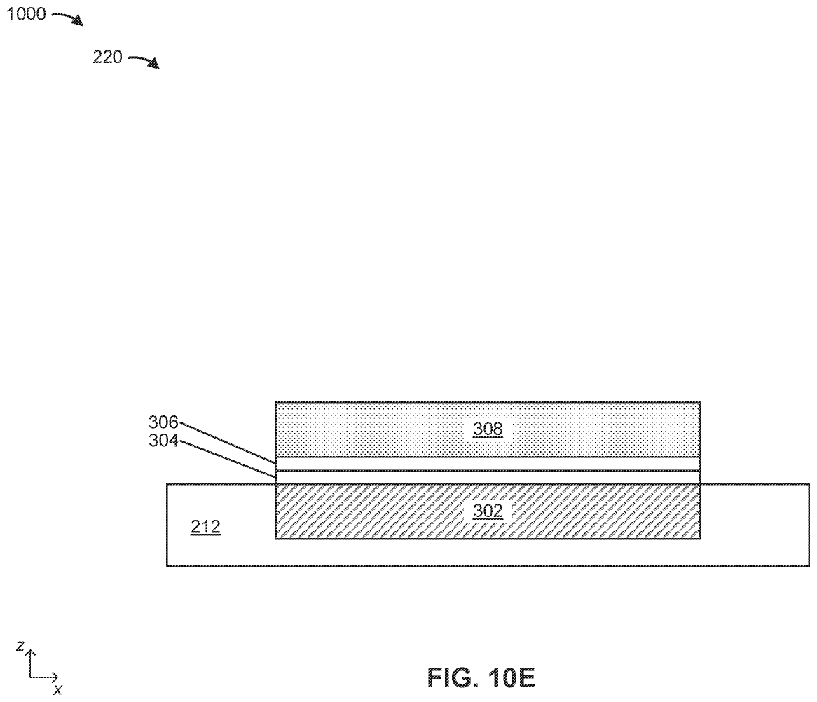

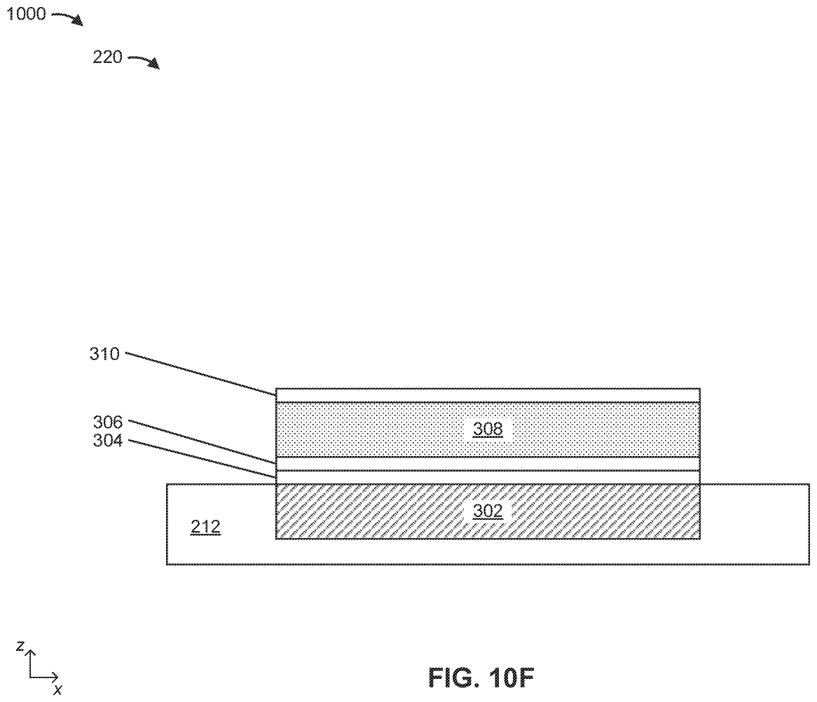

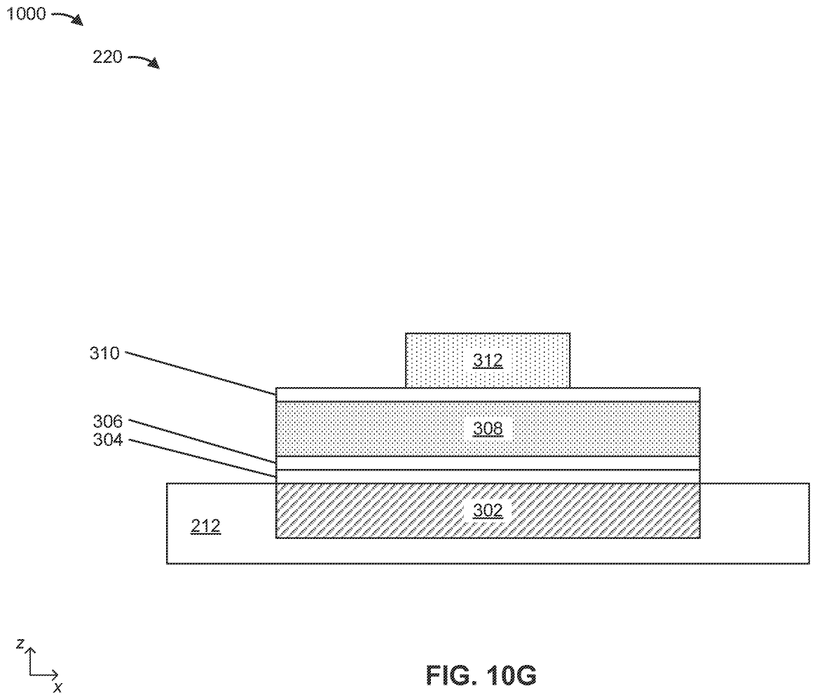

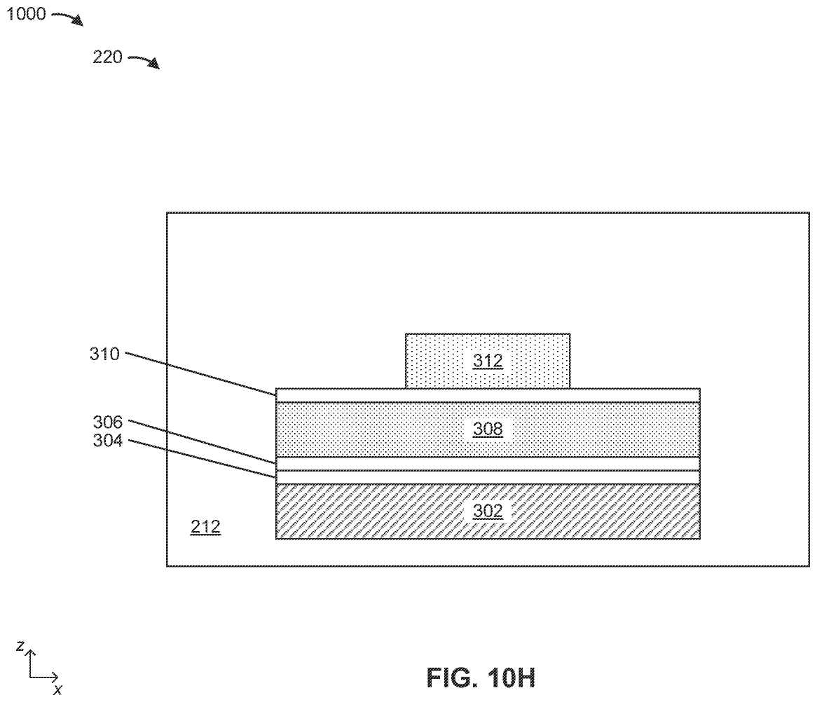

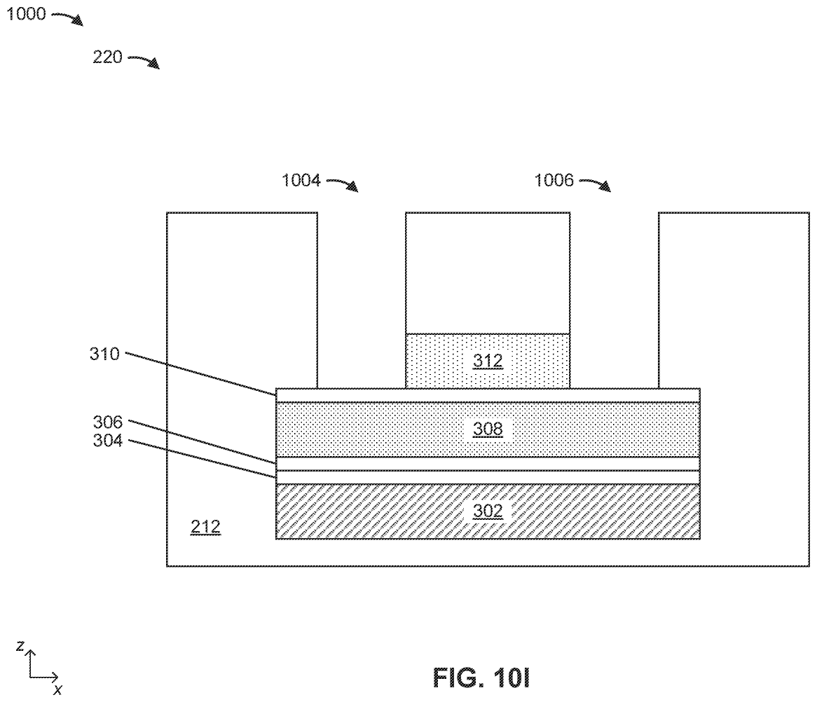

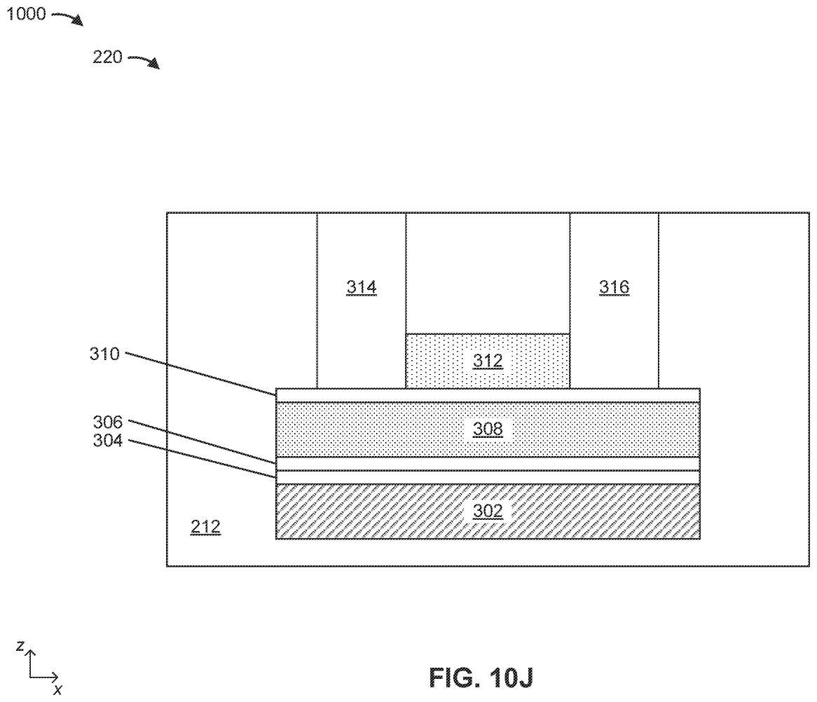

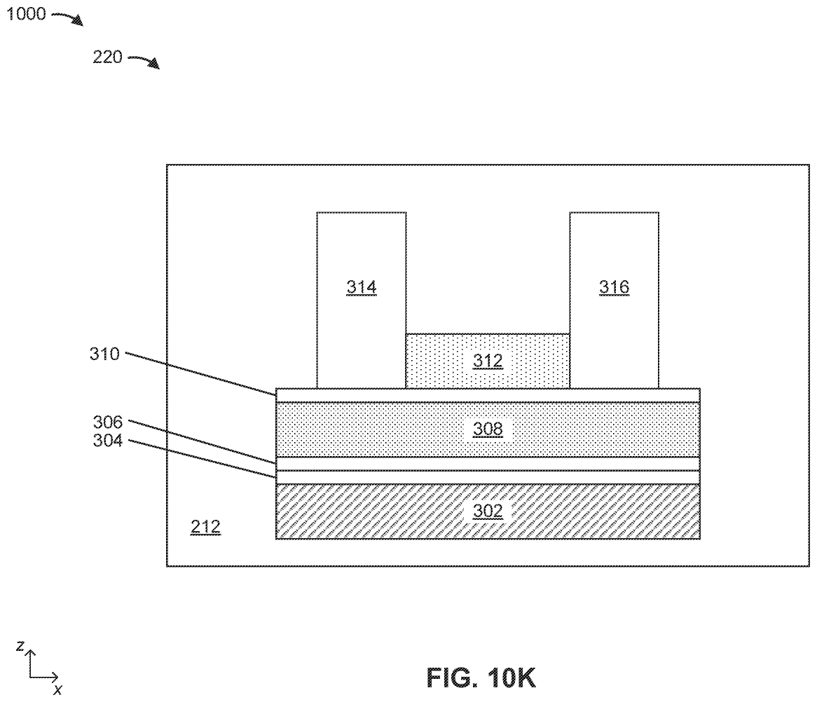

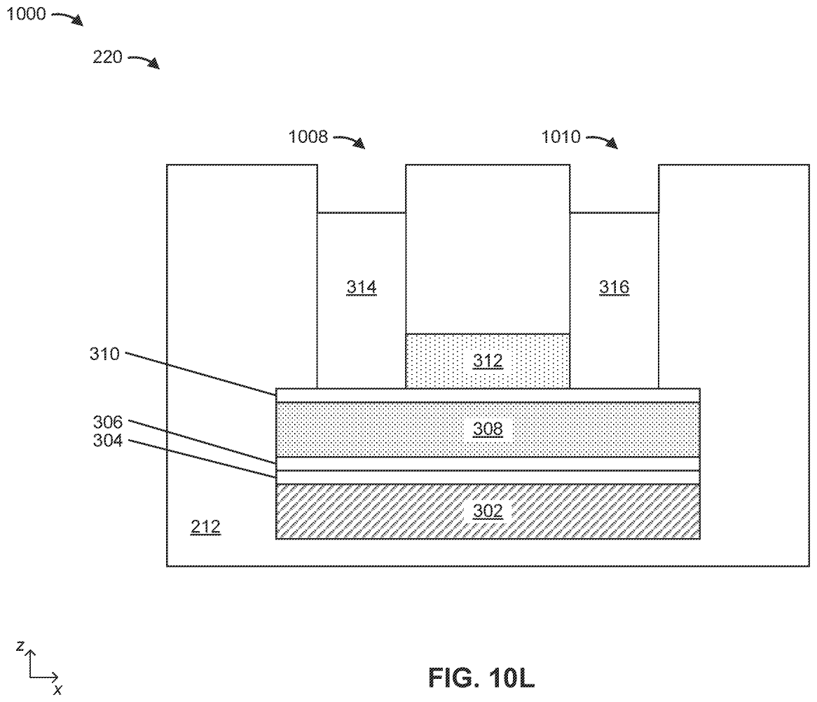

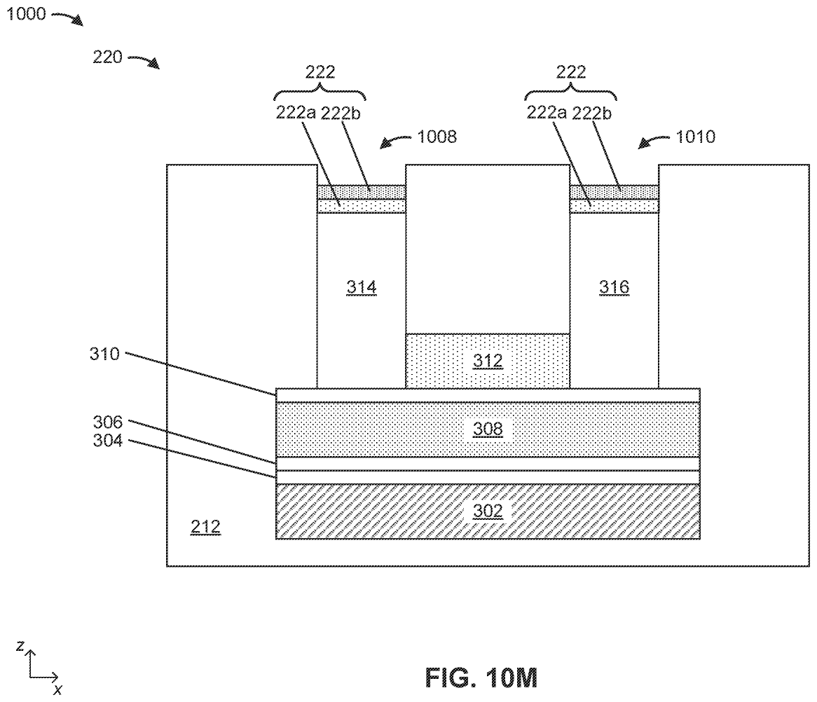

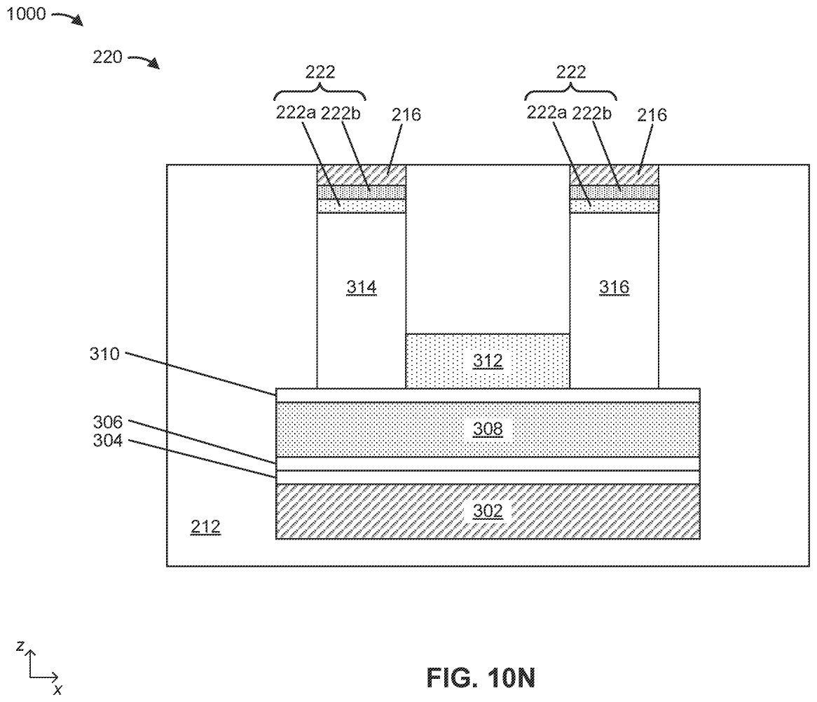

As shown in FIG. 8E, a second portion of the interconnect structure 204 of the semiconductor device 200 is formed over and/or on the first portion of the interconnect structure 204. Techniques similar to those described in connection with FIG. 8D may be performed to form the second portion of the interconnect structure 204. Additionally a non-volatile memory structure 220 is formed in an ILD layer 212 in the second portion of the interconnect structure 204. Conductive structures 216 may be formed on the non-volatile memory structure 220 to electrically connect the non-volatile memory structure 220 in the interconnect structure 204. An example implementation of forming the non-volatile memory structure 220 is illustrated and described in connection with FIGS. 10A-10N.

As further shown in FIG. 8E, one or more hydrogen barrier layers 222 may be formed on the non-volatile memory structure 220, and the conductive structures 216 coupled with the non-volatile memory structure 220 may be formed on the one or more hydrogen barrier layers 222. In some implementations, forming a hydrogen barrier layer 222 includes forming a hydrogen absorption layer 222a on the non-volatile memory structure 220, and forming a hydrogen blocking layer 222b on the hydrogen absorption layer 222a. A conductive structure 216 may then be formed on the hydrogen blocking layer 222b. In some implementations, forming a hydrogen barrier layer 222 includes forming a hydrogen absorption layer 222a on the non-volatile memory structure 220, and forming a conductive structure 216 on the hydrogen absorption layer 222a. In some implementations, forming a hydrogen barrier layer 222 includes forming a hydrogen blocking layer 222b on the non-volatile memory structure 220, and forming a conductive structure 216 on the hydrogen blocking layer 222b.

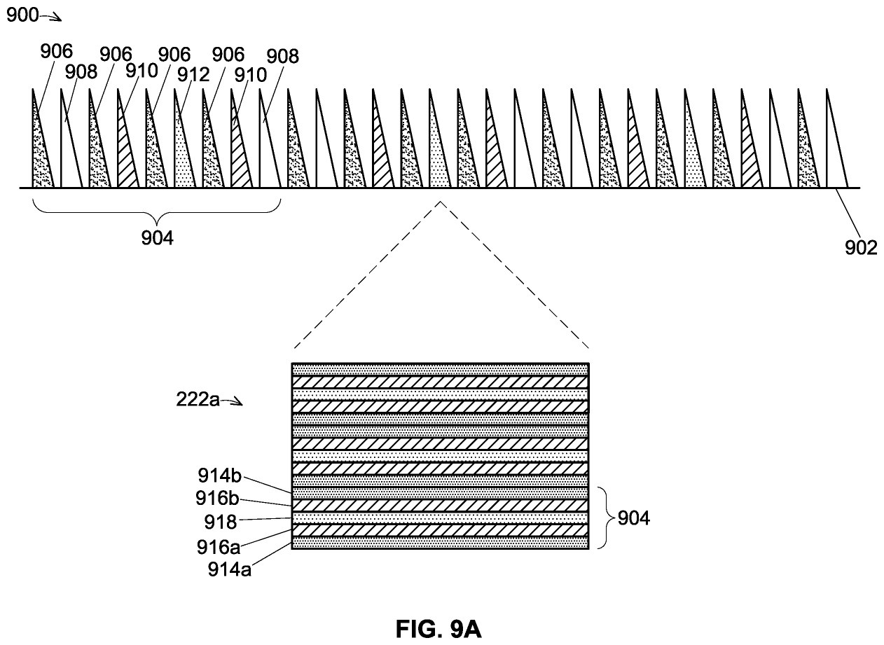

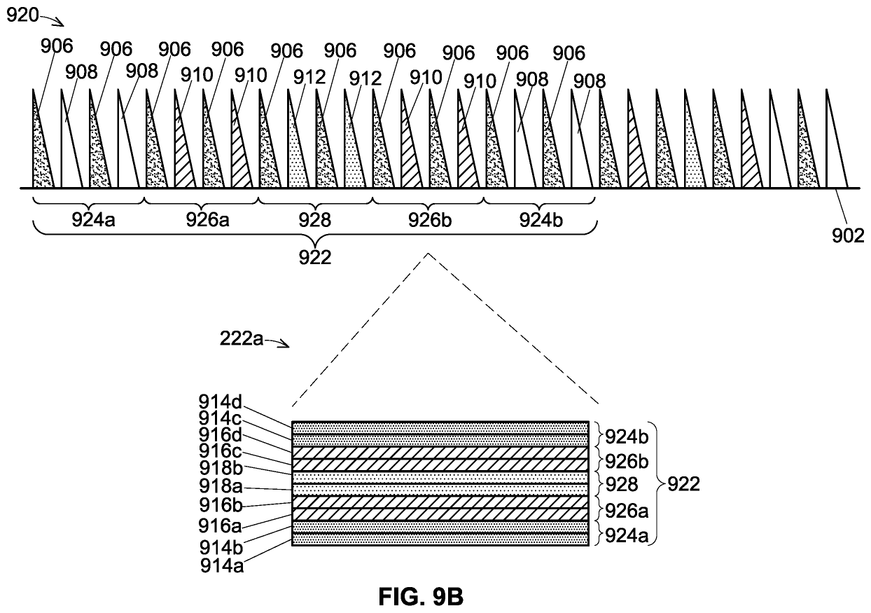

A hydrogen absorption layer 222a may be formed using a deposition tool 102. In some implementations, the deposition tool 102 is used to deposit the hydrogen absorption layer 222a using an ALD technique, such as an ALD technique illustrated and described in connection with FIGS. 9A and/or 9B. In some implementations, the deposition tool 102 is used to deposit the hydrogen absorption layer 222a using another deposition technique, such as a PVD technique, a CVD technique, an oxidation technique, another type of deposition technique described in connection with FIG. 1, and/or another suitable deposition technique.

A hydrogen blocking layer 222b may be formed using a deposition tool 102. In some implementations, the deposition tool 102 is used to deposit the hydrogen blocking layer 222b using a PVD technique such as a sputtering technique. In some implementations, the deposition tool 102 is used to deposit the hydrogen blocking layer 222b using another deposition technique, such as a PLD technique, an ALD technique, a CVD technique, an oxidation technique, another type of deposition technique described in connection with FIG. 1, and/or another suitable deposition technique. In some implementations, forming the hydrogen blocking layer 222b includes forming one or more of the example implementations of multiple-layer stacks illustrated and described in connection with FIGS. 6A-6F.

As shown in FIGS. 8F-8I, a third portion of the interconnect structure 204 is formed above the second portion of the interconnect structure 204, and above the non-volatile memory structure 220. As shown in FIG. 8F, an ESL 214 and an ILD layer 212 are formed above the non-volatile memory structure 220. A deposition tool 102 may be used to deposit the ILD layer 212 and/or the ESL 214 using a PVD technique, an ALD technique, a CVD technique, an oxidation technique, another type of deposition technique described in connection with FIG. 1, and/or another suitable deposition technique. In some implementations, the planarization tool 110 may be used to planarize the ILD layer 212 and/or the ESL 214 after the ILD layer 212 and/or the ESL 214 is deposited.

As shown in FIG. 8G, recesses 802 are formed in and/or through the ILD layer 212 and the ESL 214. The recesses 802 may be formed over one or more of the conductive structures 216 such that the one or more conductive structures 216 are exposed through the recesses 802. In some implementations, a pattern in a photoresist layer is used to etch the ILD layer 212 and/or the ESL 214 to form the recesses 802. In these implementations, a deposition tool 102 may be used to form the photoresist layer on the ILD layer 212. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the ILD layer 212 and/or the ESL 214 based on the pattern to form the recesses 802. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 212 and/or the ESL 214 based on a pattern.

As further shown in FIG. 8H, one or more hydrogen barrier layers 222 may be formed on the top surfaces of the conductive structures 216 exposed through the recesses 802. In some implementations, forming a hydrogen barrier layer 222 includes forming a hydrogen absorption layer 222a on a conductive structure 216 in a recess 802, and forming a hydrogen blocking layer 222b on the hydrogen absorption layer 222a. In some implementations, forming a hydrogen barrier layer 222 includes forming only a hydrogen absorption layer 222a on a conductive structure 216 in a recess 802. In some implementations, forming a hydrogen barrier layer 222 includes forming only a hydrogen blocking layer 222b on a conductive structure 216 in a recess 802.

A hydrogen absorption layer 222a may be formed using a deposition tool 102. In some implementations, the deposition tool 102 is used to deposit the hydrogen absorption layer 222a using an ALD technique, such as an ALD technique illustrated and described in connection with FIGS. 9A and/or 9B. In some implementations, the deposition tool 102 is used to deposit the hydrogen absorption layer 222b using another deposition technique, such as a PVD technique, a CVD technique, an oxidation technique, another type of deposition technique described in connection with FIG. 1, and/or another suitable deposition technique.

A hydrogen blocking layer 222b may be formed using a deposition tool 102. In some implementations, the deposition tool 102 is used to deposit the hydrogen blocking layer 222b using a PVD technique such as a sputtering technique. In some implementations, the deposition tool 102 is used to deposit the hydrogen absorption layer 222b using another deposition technique, such as a PLD technique, an ALD technique, a CVD technique, an oxidation technique, another type of deposition technique described in connection with FIG. 1, and/or another suitable deposition technique. In some implementations, forming the hydrogen blocking layer 222b includes forming one or more of the example implementations of multiple-layer stacks illustrated and described in connection with FIGS. 6A-6F.

As shown in FIG. 8I, conductive structures 216 are formed in the recesses 802. In particular, the conductive structures 216 are formed on the hydrogen barrier layers 222 in the recesses 802 such that the hydrogen barrier layers 222 are included between vertically adjacent conductive structures 216 (e.g., conductive structures 216 that are adjacent in the z-direction) in the interconnect structure 204.

A deposition tool 102 and/or a plating tool 112 may deposit the conductive structures 216 in the recess 802 using a CVD technique, a PVD technique, an ALD technique, an electroplating technique, another deposition technique described above in connection with FIG. 1, and/or a deposition technique other than as described above in connection with FIG. 1. In some implementations, a planarization tool 110 may perform a CMP operation to planarize the conductive structures 216 after the conductive structures 216 are deposited.

As shown in FIG. 8J, a fourth portion of the interconnect structure 204 may be formed above the third portion of the interconnect structure 204. The fourth portion of the interconnect structure 204 may be formed using a similar combination of techniques as described in connection with FIGS. 8F-8I such that hydrogen barrier layers 222 are included between the conductive structures 216 in the third portion of the interconnect structure 204 and the conductive structures 216 included in the fourth portion of the interconnect structure 204.

As shown in FIG. 8K, the connection structures 218 are formed on the interconnect structure 204 such that the connection structures 218 are electrically coupled and/or physically coupled with one or more conductive structures 216 in the interconnect structure 204. A deposition tool 102 and/or a plating tool 112 may be used to deposit the connection structures 218 using a CVD technique, a PVD technique, an ALD technique, an electroplating technique, another deposition technique described above in connection with FIG. 1, and/or a deposition technique other than as described above in connection with FIG. 1. In some implementations, a semiconductor packaging tool attaches the connection structures 218 to the semiconductor device 200.

As indicated above, FIGS. 8A-8K are provided as an example. Other examples may differ from what is described with regard to FIGS. 8A-8K.

FIGS. 9A and 9B are diagrams of example implementations of forming a hydrogen absorption layer 222a of a hydrogen barrier layer 222 described herein. The techniques described in connection with FIGS. 9A and 9B may be performed using one or more of the semiconductor processing tools 102-112 described herein, such as a deposition tool 102 (e.g., an ALD tool).

FIG. 9A illustrates an example implementation 900 of forming a hydrogen absorption layer 222a of a hydrogen barrier layer 222 described herein. The example implementation 900 includes an example ALD technique in which a layer-by-layer crystal structure is formed for a hydrogen absorption layer 222a. A plurality of operations in the ALD technique are performed as a function of time 902.

As shown in FIG. 9A, a plurality of ALD cycles 904 are performed to form the hydrogen absorption layer 222a. An ALD cycle 904 in the example implementation 900 includes the use of sequential gas-phase precursors (or reactants). The semiconductor device 200 is placed in a processing chamber of the deposition tool 102, and an oxygen-containing gas 906 is pulsed in the ALD cycle 904 to perform an oxygen treatment on the semiconductor device 020. The oxygen-containing gas 906 may include ozone (O₃), oxygen (O₂), water vapor (H₂O), and/or another oxygen-containing gas. The duration of the pulse of the oxygen-containing gas 906 may be included in a range of approximately 0.1 seconds to approximately 3 seconds. However, other values for the range are within the scope of the present disclosure.

The pulse of the oxygen-containing gas 906 is followed by a first pulse of a first metal material precursor 908, in which the first metal material precursor 908 is provided to the processing chamber of the deposition tool 102. The first metal material precursor 908 may include an indium (In) gas-phase precursor for an IGZO hydrogen absorption layer 222a. Examples of indium precursors include indium (III) acetate 99.99% trace metals basis (C6H9InO6), indium (III) acetate hydrate 99.99% trace metals basis (C6H9InO6 xH2O), and/or indium (III) acetylacetonate ≥99.99% trace metals basis (C15H21InO6), among other examples. The duration of the first pulse of the first metal material precursor 908 may be included in a range of approximately 0.1 seconds to approximately 3 seconds. However, other values for the range are within the scope of the present disclosure.

The first metal material precursor 908 is subsequently purged from the processing chamber, and another pulse of the oxygen-containing gas 906 is provided to the processing chamber. The pulse of the oxygen-containing gas 906 is followed by a pulse of a second metal material precursor 910a, in which the second metal material precursor 910a is provided to the processing chamber of the deposition tool 102. The second metal material precursor 910a may include a zinc (Zn) gas-phase precursor for an IGZO hydrogen absorption layer 222a. Examples of tin precursors include approximately 99.9999% pure tin, bis(pentafluorophenyl) zinc 97% ((C6F5)2Zn), bis(2,2,6,6-tetramethyl-3,5-heptanedionato)zinc (II) 97% (Zn(OCC(CH3)3CHCOC(CH3)3)2), diethylzinc ≥52 wt. % Zn basis (C2H5)2Zn), and/or diphenylzinc 92% (C6H5)2Zn), among other examples. The duration of the pulse of the second metal material precursor 910a may be included in a range of approximately 0.1 seconds to approximately 3 seconds. However, other values for the range are within the scope of the present disclosure.

The second metal material precursor 910a is subsequently purged from the processing chamber, and another pulse of the oxygen-containing gas 906 is provided to the processing chamber. The pulse of the oxygen-containing gas 906 is followed by a pulse of a semiconductor material precursor 912, in which the semiconductor material precursor 912 is provided to the processing chamber of the deposition tool 102. The semiconductor material precursor 912 may include a gallium (Ga) gas-phase precursor for an IGZO hydrogen absorption layer 222a. Examples of gallium precursors include triethylgallium ((CH3CH2)3Ga), trimethylgallium (Ga(CH3)3), and/or tris(dimethylamido)gallium(III) 98% (C12H36Ga2N6), among other examples. The duration of the pulse of the semiconductor material precursor 912 may be included in a range of approximately 0.1 seconds to approximately 3 seconds. However, other values for the range are within the scope of the present disclosure.

The semiconductor material precursor 912 is subsequently purged from the processing chamber, and another pulse of the oxygen-containing gas 906 is provided to the processing chamber. The pulse of the oxygen-containing gas 906 is followed by back-to-back pulses of the second metal material precursor 910 and the first metal material precursor 908. In other words, a second pulse of the second metal material precursor 910 is provided to the processing chamber of the deposition tool 102, the second metal material precursor 910 is subsequently removed from the processing chamber, and a second pulse of the first metal material precursor 908 is provided to the processing chamber without an intervening pulse of the oxygen-containing gas 906.

Alternatively, a tin (Sn) gas-phase precursor may be used in place of either the first metal material precursor 908 (e.g., to form a ZnSnO hydrogen absorption layer 222a) or the second metal material precursor 910 (e.g., to form an InSnO hydrogen absorption layer). Examples of tin precursors include bis[bis(trimethylsilyl)amino]tin(II) ([[(CH3)3Si]2N]2Sn), tetraallyltin 97% ((H2C═CHCH2)4Sn), tetrakis(diethylamido)tin(IV) ([(C2H5)2N]4Sn), tetrakis(dimethylamido)tin(IV) 99.9% trace metals basis ([(CH3)2N]4Sn), tetramethyltin 95% green alternative (SN(CH3)4), tetravinyltin 97% (Sn(CH═CH2)4), tin(II) acetylacetonate 99.9% trace metals basis (C10H14O4Sn), trimethyl(phenylethynyl)tin 97% (C6H5C≡CSn(CH3)3), and/or trimethyl(phenyl)tin 98% (C6H5Sn(CH3)3), among other examples.

The first pulse of the first metal material precursor 908 may react with the oxygen-containing gas 906 to form a metal oxide portion 914a of the hydrogen absorption layer 222a. The metal oxide portion 914a includes an oxygenized metal material (e.g., a metal oxide material) that includes the metal of the first metal material precursor 908. The first pulse of the second metal material precursor 910 may react with the oxygen-containing gas 906 to form a metal oxide portion 916a of the hydrogen absorption layer 222a on the metal oxide portion 914a. The metal oxide portion 916a includes an oxygenized metal material (e.g., a metal oxide material) that includes the metal of the second metal material precursor 910. The pulse of the semiconductor material precursor 912 may react with the oxygen-containing gas 906 to form an oxide-semiconductor portion 918 of the hydrogen absorption layer 222a on the metal oxide portion 916a. The oxide-semiconductor portion 918 includes an oxygenized semiconductor material that includes the semiconductor material of the semiconductor material precursor 912. The second pulse of the second metal material precursor 910 may react with the oxygen-containing gas 906 to form a metal oxide portion 916b of the hydrogen absorption layer 222a on the oxide-semiconductor portion 918. The metal oxide portion 916b includes an oxygenized metal material (e.g., a metal oxide material) that includes the metal of the second metal material precursor 910. The second pulse of the first metal material precursor 908 may react with the oxygen-containing gas 906 to form a metal oxide portion 914b of the hydrogen absorption layer 222a on the metal oxide portion 916b. The metal oxide portion 914b includes an oxygenized metal material (e.g., a metal oxide material) that includes the metal of the first metal material precursor 908.

Additional ALD cycles 904 may be performed to form repeating layer-by-layer crystal structures shown in FIG. 9A. The quantity of ALD cycles 904 performed may be based on a thickness that is to be achieved for the hydrogen absorption layer 222a. In some implementations, the deposition rate for each ALD cycle 904 is included in a range of approximately 0.5 angstroms per ALD cycle 904 to approximately 2 angstroms per ALD cycle 904. However, other values for the range are within the scope of the present disclosure. The time duration of each ALD cycle 904 may be included in a range of approximately 3 seconds to approximately 6 seconds. However, other values for the range are within the scope of the present disclosure.

In some implementations, the repeating layer-by-layer crystal structures shown in FIG. 9A are visible in the final structure of the semiconductor device 200. In some implementations, the portions 914a, 916a, 918, 916b, and/or 914b at least partially blend together due to subsequent thermal processing. The ALD cycles 904 may each include a greater quantity of pulses of the first metal material precursor 908 and the second metal material precursor 910 than the quantity of pulses of the semiconductor material precursor 912 to achieve a high nitrogen concentration in the hydrogen absorption layer 222a.

FIG. 9B illustrates an example implementation 920 of forming a hydrogen absorption layer 222a of a hydrogen barrier layer 222 described herein. In the example implementation 920, An ALD super cycle 922 is performed in which a plurality of precursor cycles are performed to form the portions of the hydrogen absorption layer 222a to a greater thickness than in the example implementation 900. This results in greater visible distinction between the portions of the hydrogen absorption layer 222a in the final structure, resulting in a more pronounced visible layer-by-layer crystal structure for the hydrogen absorption layer 222a.

As shown in FIG. 9B, a first metal material precursor cycle 924a is performed in which a first pulse of the oxygen-containing gas 906, a first pulse of the first metal material precursor 908, a second pulse of the oxygen-containing gas 906, and a second pulse of the first metal material precursor 908 are sequentially performed. The first metal material precursor cycle 924a in the ALD super cycle 922 is performed to deposit metal oxide portions 914a and 914b of the hydrogen absorption layer 222a.

A second metal material precursor cycle 926a is performed after the first metal material precursor cycle 924a. In the second metal material precursor cycle 926a, a first pulse of the oxygen-containing gas 906, a first pulse of the second metal material precursor 910, a second pulse of the oxygen-containing gas 906, and a second pulse of the second metal material precursor 910 are sequentially performed. The second metal material precursor cycle 926a in the ALD super cycle 922 is performed to deposit metal oxide portions 916a and 916b of the hydrogen absorption layer 222a on the metal oxide portions 914a and 914b.

A semiconductor material precursor cycle 928 is performed after the second metal material precursor cycle 926a. In the semiconductor material precursor cycle 928, a first pulse of the oxygen-containing gas 906, a first pulse of the semiconductor material precursor 912, a second pulse of the oxygen-containing gas 906, and a second pulse of the semiconductor material precursor 912 are sequentially performed. The semiconductor material precursor cycle 928 in the ALD super cycle 922 is performed to deposit oxide-semiconductor portions 918a and 918b of the hydrogen absorption layer 222a on the metal oxide portions 916a and 916b.

Another second metal material precursor cycle 926b is performed after the semiconductor material precursor cycle 928. In the second metal material precursor cycle 926b, a first pulse of the oxygen-containing gas 906, a first pulse of the second metal material precursor 910, a second pulse of the oxygen-containing gas 906, and a second pulse of the second metal material precursor 910 are sequentially performed. The second metal material precursor cycle 926b in the ALD super cycle 922 is performed to deposit metal oxide portions 916c and 916d of the hydrogen absorption layer 222a on the oxide-semiconductor portions 918a and 918b.

Another first metal material precursor cycle 924b is performed after the second metal material precursor cycle 926b. In the first metal material precursor cycle 924b, a first pulse of the oxygen-containing gas 906, a first pulse of the first metal material precursor 908, a second pulse of the oxygen-containing gas 906, and a second pulse of the first metal material precursor 908 are sequentially performed. The first metal material precursor cycle 924b in the ALD super cycle 922 is performed to deposit metal oxide portions 914c and 914d of the hydrogen absorption layer 222a on the metal oxide portions 916c and 916d.

As indicated above, FIGS. 9A and 9B are provided as examples. Other examples may differ from what is described with regard to FIGS. 9A and 9B.

FIGS. 10A-10N are diagrams of an example implementation 1000 of forming the non-volatile memory structure 220 described herein. In some implementations, one or more of the semiconductor processing operations described in connection with FIGS. 10A-10N may be performed using one or more of the semiconductor processing tools 102-112 described herein. In some implementations, one or more of the semiconductor processing operations described in connection with FIGS. 10A-10N may be performed using another type of semiconductor processing tool.

As shown in FIG. 10A, the operations described in the example implementation 1000 may be performed in connection with an ILD layer 212 of the interconnect structure 204 of the semiconductor device 200.

As shown in FIGS. 10B and 10C, the bottom gate electrode 302 may be formed in the ILD layer 212. The bottom gate electrode 302 may be formed in a recess 1002 in the ILD layer 212. Alternatively, the bottom gate electrode 302 may be formed on the ILD layer 212.

In some implementations, a pattern in a photoresist layer is used to etch the ILD layer 212 to form a recess 1002. In these implementations, a deposition tool 102 may be used to form the photoresist layer on the ILD layer 212. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the ILD layer 212 based on the pattern to form the recess 1002 in the ILD layer 212. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 212 based on a pattern.

A deposition tool 102 and/or a plating tool 112 may deposit the bottom gate electrode 302 in the recess 1002 using a CVD technique, a PVD technique, an ALD technique, an electroplating technique, another deposition technique described above in connection with FIG. 1, and/or a deposition technique other than as described above in connection with FIG. 1. In some implementations, a planarization tool 110 may perform a CMP operation to planarize the bottom gate electrode 302 after the bottom gate electrode 302 is deposited.

As shown in FIG. 10D, the interfacial layer 304 may be formed over and/or on the ILD layer 212 and over and/or on the bottom gate electrode 302. As further shown in FIG. 10D, the seed layer 306 may be formed over and/or on the interfacial layer 304. In some implementations, a deposition tool 102 may be used to perform an in-situ thermal annealing operation, which may include thermally annealing the interfacial layer 304 and/or the seed layer 306 while the deposition tool 102 is used to deposit the interfacial layer 304 and/or the seed layer 306. The thermal annealing operation may increase the crystallinity of the interfacial layer 304 and/or the seed layer 306. The deposition tool 102 may be used to deposit the interfacial layer 304 and/or the seed layer 306 using an ALD technique or a pulse layer deposition (PLD) technique. The deposition tool 102 may heat the interfacial layer 304 and/or the seed layer 306 to a temperature that is included in a range of approximately 300 degrees Celsius to approximately 700 degrees Celsius for approximately 30 seconds to approximately 10 minutes to achieve crystallinity of the interfacial layer 304 and/or the seed layer 306. However, other values for these ranges are within the scope of the present disclosure. Moreover, the interfacial layer 304 may be formed as a quasi-single crystal metal oxide.

As shown in FIG. 10E, the ferroelectric layer 308 may be formed over and/or on the seed layer 306. The seed layer 306 facilitates growth of the ferroelectric layer 308 in a particular crystal structure and/or to a particular grain size. A deposition tool 102 may be used to deposit the ferroelectric layer 308 using an ALD technique, a CVD technique, a PVD technique, another deposition technique described above in connection with FIG. 1, and/or a deposition technique other than as described above in connection with FIG. 1. In some implementations, a planarization tool 110 may perform a CMP operation to planarize the ferroelectric layer 308 after the ferroelectric layer 308 is deposited.

As shown in FIG. 10F, the blocking layer 310 may be formed over and/or on the ferroelectric layer 308. A deposition tool 102 may be used to deposit the blocking layer 310 using an ALD technique, a CVD technique, a PVD technique, another deposition technique described above in connection with FIG. 1, and/or a deposition technique other than as described above in connection with FIG. 1. In some implementations, a planarization tool 110 may perform a CMP operation to planarize the blocking layer 310 after the blocking layer 310 is deposited.

As shown in FIG. 10G, the metal-oxide channel layer 312 may be formed over and/or on the blocking layer 310. A deposition tool 102 may be used to deposit the metal-oxide channel layer 312 using an ALD technique, a CVD technique, a PVD technique, another deposition technique described above in connection with FIG. 1, and/or a deposition technique other than as described above in connection with FIG. 1. In some implementations, a planarization tool 110 may perform a CMP operation to planarize metal-oxide channel layer 312 after the metal-oxide channel layer 312 is deposited. In some implementations, a mixture of precursor gases (which may be referred to as a “cocktail”) for depositing the metal-oxide channel layer 312 may be selected to achieve a suitable electron mobility and surface state for the metal-oxide channel layer 312. The mixture may include a mixture of solid metal precursors. The mixture may be vaporized using a low pressure vessel (LPV), and the resulting vaporized precursor mixture may be introduced (e.g., pulsed) into an ALD reaction chamber containing the non-volatile memory structure 220. The vaporized precursor mixture may react with the blocking layer 310 and/or the ferroelectric layer 308 when the metal-oxide channel layer 312 is deposited.

As shown in FIG. 10H, additional material of the ILD layer 212 may be formed over and/or on the metal-oxide channel layer 312. Moreover, the additional material of the ILD layer 212 may be formed such that the non-volatile memory structure 220 is encapsulated by the ILD layer 212. A deposition tool 102 may be used to deposit the additional material of the ILD layer 212 using an ALD technique, a CVD technique, a PVD technique, an oxidation technique, another deposition technique described above in connection with FIG. 1, and/or a deposition technique other than as described above in connection with FIG. 1. In some implementations, a planarization tool 110 may perform a CMP operation to planarize the ILD layer 212 after the additional material of the ILD layer 212 is deposited.

As shown in FIG. 10I, recesses 1004 and 1006 may be formed in and/or through the ILD layer 212 such that sidewalls of the metal-oxide channel layer 312 are exposed through the recesses 1004 and 1006. In some implementations, a pattern in a photoresist layer is used to etch the ILD layer 212 to form the recesses 1004 and 1006. In these implementations, the deposition tool 102 may be used to form the photoresist layer on the ILD layer 212. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the ILD layer 212 based on the pattern to form the recesses 1004 and 1006 in the ILD layer 212. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 212 based on a pattern.

As shown in FIG. 10J, the source/drain electrodes 314 and 316 are respectively formed in the recesses 1004 and 1006. A deposition tool 102 and/or a plating tool 112 may be used to deposit the source/drain electrodes 314 and 316 using a CVD technique, a PVD technique, an ALD technique, an electroplating technique, another deposition technique described above in connection with FIG. 1, and/or another suitable deposition technique. In some implementations, the planarization tool 110 may be used to planarize the source/drain electrodes 314 and 316 after the source/drain electrodes 314 and 316 are deposited. The planarization of the source/drain electrodes 314 and 316 results in the top surfaces of the source/drain electrodes 314 and 316 and the top surface of the ILD layer 212 being substantially co-planar.

As shown in FIG. 10K, additional material of the ILD layer 212 may be formed over and/or on the source/drain electrodes 314 and 316. A deposition tool 102 may be used to deposit the additional material of the ILD layer 212 using an ALD technique, a CVD technique, a PVD technique, an oxidation technique, another deposition technique described above in connection with FIG. 1, and/or a deposition technique other than as described above in connection with FIG. 1. In some implementations, a planarization tool 110 may perform a CMP operation to planarize the ILD layer 212 after the additional material of the ILD layer 212 is deposited.

As shown in FIG. 10L, recesses 1008 and 1010 may be formed in and/or through the ILD layer 212 such that top surfaces of the source/drain electrodes 314 and 316 are exposed through the recesses 1008 and 1010, respectively. In some implementations, a pattern in a photoresist layer is used to etch the ILD layer 212 to form the recesses 1008 and 1010. In these implementations, the deposition tool 102 may be used to form the photoresist layer on the ILD layer 212. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the ILD layer 212 based on the pattern to form the recesses 1008 and 1010 in the ILD layer 212. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 212 based on a pattern.

As shown in FIG. 10M, hydrogen barrier layers 222 are formed on the top surfaces of the source/drain electrodes 314 and 316 in the recesses 1008 and 1010, respectively. For example, a hydrogen absorption layer 222a of a hydrogen barrier layer 222 may be formed on the top surface of the source/drain electrode 314 in the recess 1008, and a hydrogen blocking layer 222b of the hydrogen barrier layer 222 may be formed on the hydrogen absorption layer 222a that is on the top surface of the source/drain electrode 314 in the recess 1008. As another example, a hydrogen absorption layer 222a of a hydrogen barrier layer 222 may be formed on the top surface of the source/drain electrode 316 in the recess 1010, and a hydrogen blocking layer 222b of the hydrogen barrier layer 222 may be formed on the hydrogen absorption layer 222a that is on the top surface of the source/drain electrode 316 in the recess 1010. In some implementations, the hydrogen absorption layer(s) 222a are formed using one or more techniques described in connection with FIGS. 9A and/or 9B.

As shown in FIG. 10N, conductive structures 216 are formed on the hydrogen barrier layers 222 over the source/drain electrodes 314 and 316 in the recesses 1008 and 1010, respectively. A deposition tool 102 and/or a plating tool 112 may be used to deposit the conductive structures 216 using a CVD technique, a PVD technique, an ALD technique, an electroplating technique, another deposition technique described above in connection with FIG. 1, and/or another suitable deposition technique. In some implementations, the planarization tool 110 may be used to planarize the conductive structures 216 after the conductive structures 216 are deposited.

As indicated above, FIGS. 10A-10N are provided as an example. Other examples may differ from what is described with regard to FIGS. 10A-10N.

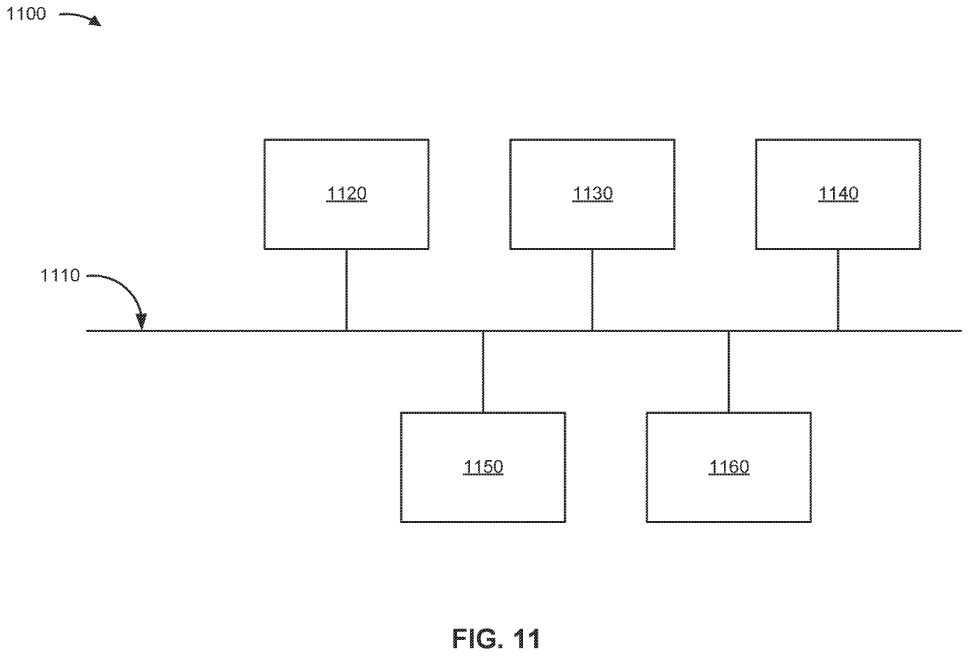

FIG. 11 is a diagram of example components of a device 1100 described herein. In some implementations, one or more of the semiconductor processing tools 102-112 and/or the wafer/die transport tool 114 may include one or more devices 1100 and/or one or more components of the device 1100. As shown in FIG. 11, the device 1100 may include a bus 1110, a processor 1120, a memory 1130, an input component 1140, an output component 1150, and/or a communication component 1160.

The bus 1110 may include one or more components that enable wired and/or wireless communication among the components of the device 1100. The bus 1110 may couple together two or more components of FIG. 11, such as via operative coupling, communicative coupling, electronic coupling, and/or electric coupling. For example, the bus 1110 may include an electrical connection (e.g., a wire, a trace, and/or a lead) and/or a wireless bus. The processor 1120 may include a central processing unit, a graphics processing unit, a microprocessor, a controller, a microcontroller, a digital signal processor, a field-programmable gate array, an application-specific integrated circuit, and/or another type of processing component. The processor 1120 may be implemented in hardware, firmware, or a combination of hardware and software. In some implementations, the processor 1120 may include one or more processors capable of being programmed to perform one or more operations or processes described elsewhere herein.

The memory 1130 may include volatile and/or nonvolatile memory. For example, the memory 1130 may include random access memory (RAM), read only memory (ROM), a hard disk drive, and/or another type of memory (e.g., a flash memory, a magnetic memory, and/or an optical memory). The memory 1130 may include internal memory (e.g., RAM, ROM, or a hard disk drive) and/or removable memory (e.g., removable via a universal serial bus connection). The memory 1130 may be a non-transitory computer-readable medium. The memory 1130 may store information, one or more instructions, and/or software (e.g., one or more software applications) related to the operation of the device 1100. In some implementations, the memory 1130 may include one or more memories that are coupled (e.g., communicatively coupled) to one or more processors (e.g., processor 1120), such as via the bus 1110. Communicative coupling between a processor 1120 and a memory 1130 may enable the processor 1120 to read and/or process information stored in the memory 1130 and/or to store information in the memory 1130.

The input component 1140 may enable the device 1100 to receive input, such as user input and/or sensed input. For example, the input component 1140 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1150 may enable the device 1100 to provide output, such as via a display, a speaker, and/or a light-emitting diode. The communication component 1160 may enable the device 1100 to communicate with other devices via a wired connection and/or a wireless connection. For example, the communication component 1160 may include a receiver, a transmitter, a transceiver, a modem, a network interface card, and/or an antenna.

The device 1100 may perform one or more operations or processes described herein. For example, a non-transitory computer-readable medium (e.g., memory 1130) may store a set of instructions (e.g., one or more instructions or code) for execution by the processor 1120. The processor 1120 may execute the set of instructions to perform one or more operations or processes described herein. In some implementations, execution of the set of instructions, by one or more processors 1120, causes the one or more processors 1120 and/or the device 1100 to perform one or more operations or processes described herein. In some implementations, hardwired circuitry may be used instead of or in combination with the instructions to perform one or more operations or processes described herein. Additionally, or alternatively, the processor 1120 may be configured to perform one or more operations or processes described herein. Thus, implementations described herein are not limited to any specific combination of hardware circuitry and software.

The number and arrangement of components shown in FIG. 11 are provided as an example. The device 1100 may include additional components, fewer components, different components, or differently arranged components than those shown in FIG. 11. Additionally, or alternatively, a set of components (e.g., one or more components) of the device 1100 may perform one or more functions described as being performed by another set of components of the device 1100.

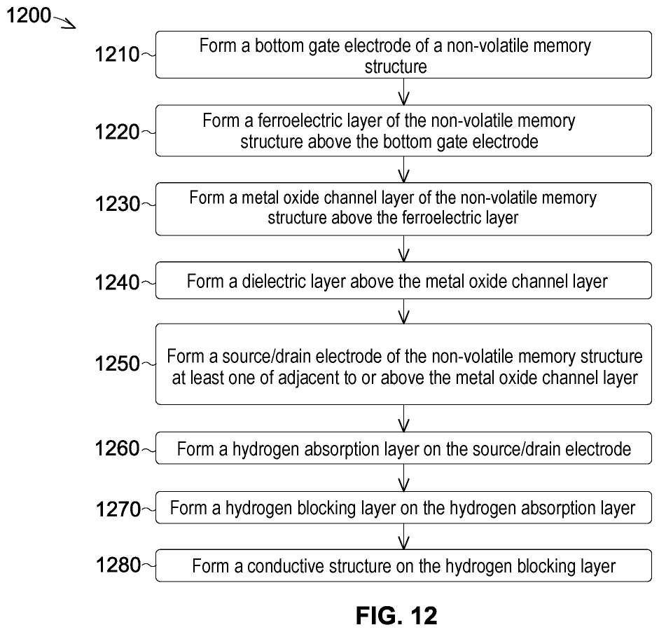

FIG. 12 is a flowchart of an example process 1200 associated with forming a non-volatile memory structure described herein. In some implementations, one or more process blocks of FIG. 12 are performed using one or more semiconductor processing tools (e.g., one or more of the semiconductor processing tools 102-112). Additionally, or alternatively, one or more process blocks of FIG. 12 may be performed using one or more components of device 1100, such as processor 1120, memory 1130, input component 1140, output component 1150, and/or communication component 1160.

As shown in FIG. 12, process 1200 may include forming a bottom gate electrode of a non-volatile memory structure (block 1210). For example, one or more of the semiconductor processing tools 102-112 may be used to form a bottom gate electrode 302 of a non-volatile memory structure 220, as described herein.

As further shown in FIG. 12, process 1200 may include forming a ferroelectric layer (308) of the non-volatile memory structure above the bottom gate electrode (block 1220). For example, one or more of the semiconductor processing tools 102-112 may be used to form a ferroelectric layer 308 of the non-volatile memory structure 220 above the bottom gate electrode 302, as described herein.

As further shown in FIG. 12, process 1200 may include forming a metal-oxide channel layer of the non-volatile memory structure above the ferroelectric layer (block 1230). For example, one or more of the semiconductor processing tools 102-112 may be used to form a metal-oxide channel layer 312 of the non-volatile memory structure 220 above the ferroelectric layer 308, as described herein.

As further shown in FIG. 12, process 1200 may include forming a dielectric layer above the metal-oxide channel layer (block 1240). For example, one or more of the semiconductor processing tools 102-112 may be used to form a dielectric layer (e.g., an ILD layer 212) above the metal-oxide channel layer 312, as described herein.

As further shown in FIG. 12, process 1200 may include forming a source/drain electrode of the non-volatile memory structure at least one of adjacent to or above the metal-oxide channel layer (block 1250). For example, one or more of the semiconductor processing tools 102-112 may be used to form a source/drain electrode (e.g., a source/drain electrode 314, a source/drain electrode 316) of the non-volatile memory structure 220 at least one of adjacent to or above the metal-oxide channel layer 312, as described herein.

As further shown in FIG. 12, process 1200 may include forming a hydrogen absorption layer on the source/drain electrode (block 1260). For example, one or more of the semiconductor processing tools 102-112 may be used to form a hydrogen absorption layer 222a on the source/drain electrode, as described herein.

As further shown in FIG. 12, process 1200 may include forming a hydrogen blocking layer on the hydrogen absorption layer (block 1270). For example, one or more of the semiconductor processing tools 102-112 may be used to form a hydrogen blocking layer 222b on the hydrogen absorption layer 222a, as described herein.

As further shown in FIG. 12, process 1200 may include forming a conductive structure on the hydrogen blocking layer (block 1280). For example, one or more of the semiconductor processing tools 102-112 may be used to form a conductive structure 216 on the hydrogen blocking layer 222b, as described herein.

Process 1200 may include additional implementations, such as any single implementation or any combination of implementations described below and/or in connection with one or more other processes described elsewhere herein.

In a first implementation, forming the source/drain electrode includes forming a first recess (e.g., a recess 1004, a recess 1006) in the dielectric layer, and forming the source/drain electrode in the first recess, where forming the hydrogen absorption layer 222a includes forming a second recess (e.g., a recess 1008, a recess 1010) in the dielectric layer such that the source/drain electrode is exposed through the second recess, and forming the hydrogen absorption layer 222a in the second recess on the source/drain electrode.

In a second implementation, alone or in combination with the first implementation, forming the hydrogen blocking layer 222b includes forming the hydrogen blocking layer 222b on the hydrogen absorption layer 222a in the second recess, where forming the conductive structure 216 includes forming the conductive structure 216 on the hydrogen blocking layer 222b in the second recess.

In a third implementation, alone or in combination with one or more of the first and second implementations, forming the hydrogen absorption layer 222a includes performing a plurality of ALD cycles 904 to deposit the hydrogen absorption layer 222a, where performing an ALD cycle 904, of the plurality of ALD cycles 904, includes depositing, using a first metal material precursor 908, a first portion (e.g., a metal oxide portion 914a) of the hydrogen absorption layer 222a, depositing, using a second metal material precursor 910, a second portion (e.g., a metal oxide portion 916a) of the hydrogen absorption layer 222a on the first portion of the hydrogen absorption layer 222a, and depositing, using a semiconductor material precursor 912, a third portion (e.g., an oxide-semiconductor portion 918) of the hydrogen absorption layer 222a on the second portion of the hydrogen absorption layer 222a.

In a fourth implementation, alone or in combination with one or more of the first through third implementations, performing the ALD cycle 904 further includes depositing, using the second metal material precursor 910, a fourth portion (e.g., a metal oxide portion 916b) of the hydrogen absorption layer 222a on the third portion of the hydrogen absorption layer 222a, and depositing, using the first metal material precursor 908, a fifth portion (e.g., a metal oxide portion 914b) of the hydrogen absorption layer 222a on the fourth portion of the hydrogen absorption layer 222a.

In a fifth implementation, alone or in combination with one or more of the first through fourth implementations, forming the hydrogen absorption layer comprises performing a plurality of ALD cycles (e.g., ALD super cycles 922) to deposit the hydrogen absorption layer 222a, where performing an ALD cycle (e.g., an ALD super cycle 922), of the plurality of ALD cycles (e.g., the ALD super cycles 922), includes depositing, using a first metal material precursor 908, a first portion (e.g., a metal oxide portion 914a) of the hydrogen absorption layer 222a, depositing, using the first metal material precursor 908, a second portion (e.g., a metal oxide portion 914b) of the hydrogen absorption layer 222a on the first portion of the hydrogen absorption layer 222a, depositing, using a second metal material precursor 910, a third portion (e.g., a metal oxide portion 916a) of the hydrogen absorption layer 222a on the second portion of the hydrogen absorption layer 222a, depositing, using the second metal material precursor 910, a fourth portion (e.g., a metal oxide portion 916b) of the hydrogen absorption layer 222a on the third portion of the hydrogen absorption layer 222a, depositing, using a semiconductor material precursor 912, a fifth portion (e.g., an oxide-semiconductor portion 918a) of the hydrogen absorption layer 222a on the fourth portion of the hydrogen absorption layer 222a, and depositing, using the semiconductor material precursor 912, a sixth portion (e.g., an oxide-semiconductor portion 918b) of the hydrogen absorption layer 222a on the fifth portion of the hydrogen absorption layer 222a.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

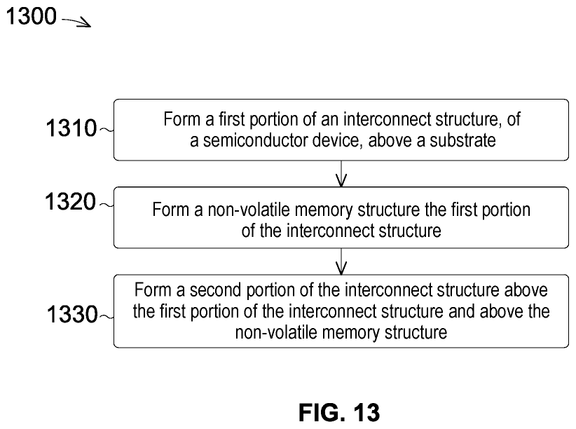

FIG. 13 is a flowchart of an example process 1300 associated with forming a semiconductor device described herein. In some implementations, one or more process blocks of FIG. 13 are performed using one or more semiconductor processing tools (e.g., one or more of the semiconductor processing tools 102-112). Additionally, or alternatively, one or more process blocks of FIG. 13 may be performed using one or more components of device 1100, such as processor 1120, memory 1130, input component 1140, output component 1150, and/or communication component 1160.

As shown in FIG. 13, process 1300 may include forming a first portion of an interconnect structure, of a semiconductor device, above a substrate (block 1310). For example, one or more of the semiconductor processing tools 102-112 may be used to form a first portion of an interconnect structure 204, of a semiconductor device 200, above a substrate 206, as described herein.

As further shown in FIG. 13, process 1300 may include forming a non-volatile memory structure the first portion of the interconnect structure (block 1320). For example, one or more of the semiconductor processing tools 102-112 may be used to form a non-volatile memory structure 220 the first portion of the interconnect structure 204, as described herein.

As further shown in FIG. 13, process 1300 may include forming a second portion of the interconnect structure above the first portion of the interconnect structure and above the non-volatile memory structure (block 1330). For example, one or more of the semiconductor processing tools 102-112 may be used to form a second portion of the interconnect structure 204 above the first portion of the interconnect structure 204 and above the non-volatile memory structure 220, as described herein. In some implementations, forming the second portion of the interconnect structure 204 includes forming one or more dielectric layers (e.g., one or more ILD layers 212, one or more ESLs 214) above the first portion of the interconnect structure 204. In some implementations, forming the second portion of the interconnect structure 204 includes forming a recess 802 in the one or more dielectric layers, where a first conductive structure 216 in the first portion of the interconnect structure 204 is exposed through the recess 802. In some implementations, forming the second portion of the interconnect structure 204 includes forming a hydrogen barrier layer 222 on the first conductive structure 216 in the recess 802; and forming a second conductive structure 216 on the hydrogen barrier layer 222 in the recess 802.

Process 1300 may include additional implementations, such as any single implementation or any combination of implementations described below and/or in connection with one or more other processes described elsewhere herein.

In a first implementation, forming the hydrogen barrier layer 222 includes forming a hydrogen absorption layer 222a, of the hydrogen barrier layer 222, on the first conductive structure 216 in the recess 802, and forming a hydrogen blocking layer 222b, of the hydrogen barrier layer 222, on the hydrogen absorption layer 222a in the recess 802.

In a second implementation, alone or in combination with the first implementation, forming the second conductive structure 216 includes forming the second conductive structure 216 on the hydrogen blocking layer 222b.

In a third implementation, alone or in combination with one or more of the first and second implementations, forming the hydrogen absorption layer 222a includes forming the hydrogen absorption layer 222a to a thickness (e.g., the dimension D1) that is included in a range of approximately 10 angstroms to approximately 1000 nanometers.

In a fourth implementation, alone or in combination with one or more of the first through third implementations, forming the hydrogen blocking layer 222b includes forming the hydrogen blocking layer 222b to a thickness (e.g., the dimension D2) that is included in a range of approximately 10 angstroms to approximately 1000 nanometers.

In a fifth implementation, alone or in combination with one or more of the first through fourth implementations, process 1300 includes forming another hydrogen barrier layer 222 on the non-volatile memory structure 220 in the first portion of the interconnect structure 204 prior to forming the second portion of the interconnect structure 204.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a multiple-layer hydrogen barrier stack may be included between a non-volatile memory structure and conductive structures in an interconnect structure in a semiconductor device. The multiple-layer hydrogen barrier stack may minimize and/or prevent hydrogen diffusion into one or more layers of the non-volatile memory structure such as a metal-oxide channel of the non-volatile memory structure. The multiple-layer hydrogen barrier stack may include a hydrogen absorption layer and a hydrogen blocking layer on the hydrogen absorption layer. The hydrogen blocking layer blocks or resists diffusion of hydrogen through the conductive structures into the non-volatile memory structure. The hydrogen absorption layer may absorb any hydrogen atoms that might diffuse through the hydrogen blocking layer. The combination of the hydrogen absorption layer and the hydrogen blocking layer minimizes and/or prevents hydrogen diffusion into one or more layers of the FeRAM structure such as the metal-oxide channel of the non-volatile memory structure. This may reduce the likelihood of charge carrier concentration in the metal-oxide channel of the non-volatile memory structure, which may enable a low PBTI and/or a low NBTI to be achieved for the non-volatile memory structure. Additionally and/or alternatively, the combination of the hydrogen absorption layer and the hydrogen blocking layer may enable a low off-current leakage to be achieved for the non-volatile memory structure and/or may reduce the likelihood that the non-volatile memory structure may become non-operational because of charge carrier concentration.

As described in greater detail above, some implementations described herein provide a semiconductor device. The semiconductor device includes an interconnect structure, above a substrate of the semiconductor device, that includes a plurality of dielectric layers and a plurality of conductive structures in the plurality of dielectric layers. The semiconductor device includes non-volatile memory structure in a dielectric layer of the plurality of dielectric layers of the interconnect structure, where the non-volatile memory structure comprises a metal-oxide channel layer, and where the non-volatile memory structure is electrically coupled with at least one conductive structure of the plurality of conductive structures. The semiconductor device includes a hydrogen barrier layer between the non-volatile memory structure and the at least one conductive structure.

As described in greater detail above, some implementations described herein provide a method. The method includes forming a bottom gate electrode of a non-volatile memory structure. The method includes forming a ferroelectric layer of the non-volatile memory structure above the bottom gate electrode. The method includes forming a metal-oxide channel layer of the non-volatile memory structure above the ferroelectric layer. The method includes forming a dielectric layer above the metal-oxide channel layer. The method includes forming a source/drain electrode of the non-volatile memory structure at least one of adjacent to or above the metal-oxide channel layer. The method includes forming a hydrogen absorption layer on the source/drain electrode. The method includes forming a hydrogen blocking layer on the hydrogen absorption layer. The method includes forming a conductive structure on the hydrogen blocking layer.

As described in greater detail above, some implementations described herein provide a method. The method includes forming a first portion of an interconnect structure, of a semiconductor device, above a substrate. The method includes forming a non-volatile memory structure the first portion of the interconnect structure. The method includes forming a second portion of the interconnect structure above the first portion of the interconnect structure and above the non-volatile memory structure, where forming the second portion of the interconnect structure comprises: forming one or more dielectric layers above the first portion of the interconnect structure forming a recess in the one or more dielectric layers, where a first conductive structure in the first portion of the interconnect structure is exposed through the recess forming a hydrogen barrier layer on the first conductive structure in the recess forming a second conductive structure on the hydrogen barrier layer in the recess.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnect structure, above a substrate of the semiconductor device, comprising:
a plurality of dielectric layers; and
a plurality of conductive structures in the plurality of dielectric layers;
a non-volatile memory structure in a dielectric layer of the plurality of dielectric layers of the interconnect structure,
wherein the non-volatile memory structure comprises a metal-oxide channel layer, and
wherein the non-volatile memory structure is electrically coupled with at least one conductive structure of the plurality of conductive structures; and
a hydrogen barrier layer between the non-volatile memory structure and the at least one conductive structure.

2. The semiconductor device of claim 1, wherein the hydrogen barrier layer comprises a metal-oxide semiconductor material.

3. The semiconductor device of claim 1, wherein the hydrogen barrier layer comprises at least one of:
ruthenium (Ru),
aluminum (Al),
silver (Ag),
platinum (Pt),
gold (Au),
titanium (Ti), or
titanium nitride (TiN).

4. The semiconductor device of claim 1, wherein the hydrogen barrier layer comprises:
a hydrogen absorption layer that includes a metal-oxide-containing material; and
a hydrogen blocking layer, on the hydrogen absorption layer, that includes a metal-containing material.

5. The semiconductor device of claim 1, wherein the hydrogen barrier layer comprises:
a first titanium nitride (TiN) layer;
a metal layer on the first titanium nitride layer; and
a second titanium nitride layer on the metal layer.

6. The semiconductor device of claim 5, wherein a thickness of the metal layer is greater than a thickness of the first titanium nitride layer; and
wherein the thickness of the metal layer is greater than a thickness of the second titanium nitride layer.

7. The semiconductor device of claim 5, wherein a thickness of the metal layer and a thickness of the first titanium nitride layer are approximately equal; and
wherein the thickness of the metal layer and a thickness of the second titanium nitride layer are approximately equal.

8. The semiconductor device of claim 1, wherein the hydrogen barrier layer comprises:
a first titanium nitride (TiN) layer;
a second titanium nitride layer on the first titanium nitride layer; and
a third titanium nitride layer on the second titanium nitride layer.

9. A method, comprising:
forming a bottom gate electrode of a non-volatile memory structure;
forming a ferroelectric layer of the non-volatile memory structure above the bottom gate electrode;
forming a metal-oxide channel layer of the non-volatile memory structure above the ferroelectric layer;
forming a dielectric layer above the metal-oxide channel layer;
forming a source/drain electrode of the non-volatile memory structure at least one of adjacent to or above the metal-oxide channel layer;
forming a hydrogen absorption layer on the source/drain electrode;
forming a hydrogen blocking layer on the hydrogen absorption layer; and
forming a conductive structure on the hydrogen blocking layer.

10. The method of claim 9, wherein forming the source/drain electrode comprises:
forming a first recess in the dielectric layer; and
forming the source/drain electrode in the first recess; and
wherein forming the hydrogen absorption layer comprises:
forming a second recess in the dielectric layer,
wherein the source/drain electrode is exposed through the second recess; and
forming the hydrogen absorption layer in the second recess on the source/drain electrode.

11. The method of claim 10, wherein forming the hydrogen blocking layer comprises:
forming the hydrogen blocking layer on the hydrogen absorption layer in the second recess; and
wherein forming the conductive structure comprises:
forming the conductive structure on the hydrogen blocking layer in the second recess.

12. The method of claim 9, wherein forming the hydrogen absorption layer comprises:
performing a plurality of atomic layer deposition (ALD) cycles to deposit the hydrogen absorption layer,
wherein performing an ALD cycle, of the plurality of ALD cycles, comprises:
depositing, using a first metal material precursor, a first portion of the hydrogen absorption layer;
depositing, using a second metal material precursor, a second portion of the hydrogen absorption layer on the first portion of the hydrogen absorption layer; and
depositing, using a semiconductor material precursor, a third portion of the hydrogen absorption layer on the second portion of the hydrogen absorption layer.

13. The method of claim 12, wherein performing the ALD cycle further comprises:
depositing, using the second metal material precursor, a fourth portion of the hydrogen absorption layer on the third portion of the hydrogen absorption layer; and
depositing, using the first metal material precursor, a fifth portion of the hydrogen absorption layer on the fourth portion of the hydrogen absorption layer.

14. The method of claim 9, wherein forming the hydrogen absorption layer comprises:
performing a plurality of atomic layer deposition (ALD) cycles to deposit the hydrogen absorption layer,
wherein performing an ALD cycle, of the plurality of ALD cycles, comprises:
depositing, using a first metal material precursor, a first portion of the hydrogen absorption layer;
depositing, using the first metal material precursor, a second portion of the hydrogen absorption layer on the first portion of the hydrogen absorption layer;
depositing, using a second metal material precursor, a third portion of the hydrogen absorption layer on the second portion of the hydrogen absorption layer;
depositing, using the second metal material precursor, a fourth portion of the hydrogen absorption layer on the third portion of the hydrogen absorption layer;
depositing, using a semiconductor material precursor, a fifth portion of the hydrogen absorption layer on the fourth portion of the hydrogen absorption layer; and
depositing, using the semiconductor material precursor, a sixth portion of the hydrogen absorption layer on the fifth portion of the hydrogen absorption layer.

15. A method, comprising:
forming a first portion of an interconnect structure, of a semiconductor device, above a substrate;
forming a non-volatile memory structure the first portion of the interconnect structure; and
forming a second portion of the interconnect structure above the first portion of the interconnect structure and above the non-volatile memory structure,
wherein forming the second portion of the interconnect structure comprises:
forming one or more dielectric layers above the first portion of the interconnect structure;
forming a recess in the one or more dielectric layers,
wherein a first conductive structure in the first portion of the interconnect structure is exposed through the recess;
forming a hydrogen barrier layer on the first conductive structure in the recess; and
forming a second conductive structure on the hydrogen barrier layer in the recess.

16. The method of claim 15, wherein forming the hydrogen barrier layer comprises:
forming a hydrogen absorption layer, of the hydrogen barrier layer, on the first conductive structure in the recess; and
forming a hydrogen blocking layer, of the hydrogen barrier layer, on the hydrogen absorption layer in the recess.

17. The method of claim 16, wherein forming the second conductive structure comprises:
forming the second conductive structure on the hydrogen blocking layer.

18. The method of claim 16, wherein forming the hydrogen absorption layer comprises:
forming the hydrogen absorption layer to a thickness that is included in a range of approximately 10 angstroms to approximately 1000 nanometers.

19. The method of claim 16, wherein forming the hydrogen blocking layer comprises:
forming the hydrogen blocking layer to a thickness that is included in a range of approximately 10 angstroms to approximately 1000 nanometers.

20. The method of claim 15, further comprising:
forming another hydrogen barrier layer on the non-volatile memory structure in the first portion of the interconnect structure prior to forming the second portion of the interconnect structure.
